(19) United States
(12) Patent Application Publication
(10) Pub. No.: US 2022/0137926 A1
(43) Pub. Date: May 5, 2022

(54) ARITHMETIC APPARATUS AND MULTIPLY-ACCUMULATE SYSTEM

(71) Applicant: SONY GROUP CORPORATION, Tokyo (JP)

(72) Inventor: Hiroshi Yoshida, Kanagawa (JP)

(21) Appl. No.: 17/431,596

(22) PCT Filed: Feb. 28, 2020
(86) PCT No.: PCT/JP2020/008394

§ 371 Date: Aug. 17, 2021

(30) Foreign Application Priority Data
Mar. 27, 2019 (JP) 2019-060708

(51) Int. Cl. G06F 7/544; G06N 3/063

(52) U.S. Cl. CPC G06F 7/5443; G06N 3/063

(57) ABSTRACT

An arithmetic apparatus includes input lines and one or more multiply-accumulate devices. An electrical signal corresponding to an input value is input into the input lines within a predetermined input period. Multiplication units generate a product value by multiplying the input value by a weight value. An accumulation unit accumulates the charge corresponding to the generated product value. A charging unit charges, after the input period, the accumulation unit in which the charge corresponding to the product value is accumulated. An output unit outputs, after charging by the charging unit starts, a multiply-accumulate signal representing a sum of the product values by performing threshold determination on a voltage retained by the accumulation unit by using a predetermined threshold value. The charging by the charging unit is performed on a common charging mode and a common threshold value is set as the predetermined threshold value.

### TECHNICAL FIELD

The present technology relates to an arithmetic apparatus and a multiply-accumulate system that can be applied to a multiply-accumulate operation using an analog method.

### BACKGROUND ART

Conventionally, a technology for performing a multiply-accumulate operation has been developed. The multiply-accumulate operation is an operation of multiplying each of a plurality of input values by a weight and adding the multiplication results to each other, and is used for, for example, processing of recognizing images, voices, and the like through a neural network or the like.

For example, Patent Literature 1 describes an analog circuit in which multiply-accumulate processing is performed in an analog manner. In this analog circuit, a weight corresponding to each of a plurality of electrical signals is set. Moreover, charges depending on the corresponding electrical signals and weights are respectively output and the output charges are accumulated in a capacitor as appropriate. A value to be calculated, which represents a multiply-accumulate result, is calculated on the basis of the voltage of the capacitor in which the charges are accumulated. Accordingly, it is possible to reduce the power consumption required for the multiply-accumulate operation as compared with, for example, digital processing (paragraphs [0003], [0049] to [0053], and of specification, FIG. 3, and the like of Patent Literature 1).

### CITATION LIST

### Patent Literature

Patent Literature 1: WO 2018/034163

### DISCLOSURE OF INVENTION

### Technical Problem

The use of such an analog-type circuit is expected to lead to low power consumption of the neural network or the like, and it is desirable to provide a technology of realizing efficient and high-speed arithmetic processing.

In view of the above-mentioned circumstances, it is an object of the present technology to provide an arithmetic apparatus, a multiply-accumulate system, and a setting method by which efficient and high-speed arithmetic processing can be realized in an analog circuit that performs a multiply-accumulate operation.

### Solution to Problem

In order to accomplish the above-mentioned object, an arithmetic apparatus according to an embodiment of the present technology includes a plurality of input lines and one or more multiply-accumulate devices.

Each of which an electrical signal corresponding to an input value is input within a predetermined input period into the plurality of input lines.

The one or more multiply-accumulate devices each include a plurality of multiplication units, an accumulation unit, a charging unit, and an output unit.

The plurality of multiplication units generates, on the basis of the electrical signal input into each of the plurality of input lines, a charge corresponding to a product value obtained by multiplying the input value by a weight value.

The accumulation unit accumulates the charge corresponding to the product value generated by each of the plurality of multiplication units.

The charging unit charges, after the input period, the accumulation unit in which the charge corresponding to the product value is accumulated.

The output unit outputs, after charging by the charging unit starts, a multiply-accumulate signal representing a sum of the product values by performing threshold determination on a voltage retained by the accumulation unit by using a predetermined threshold value.

Moreover, in the one or more multiply-accumulate devices, the charging by the charging unit is performed on a common charging mode and a common threshold value is set as the predetermined threshold value.

In this arithmetic apparatus, with respect to the one or more multiply-accumulate devices, the charging is performed on the common charging mode and the threshold determination is performed by using the common threshold value. Accordingly, it is possible to realize efficient and high-speed arithmetic processing in the analog circuit that performs the multiply-accumulate operation.

The one or more multiply-accumulate devices may be a plurality of multiply-accumulate devices connected in parallel to the plurality of input lines.

The common charging mode may include charging in which a same charge signal is supplied during a common charging period.

The common charging mode may include charging at a common charging speed.

The common charging mode may include charging according to a common time constant.

Defining a sum total of absolute values of the weight values set in the plurality of multiplication units as a weight sum total value, the common charging mode may include charging based on a maximum value of the weight sum total value among the one or more multiply-accumulate devices.

Each of the one or more multiply-accumulate devices may include a charge output line. In this case, the plurality of multiplication units may output the charge corresponding to the product value to the charge output line. Moreover, the common charging mode may include charging in which a time constant associated with the output of the charge corresponding to the product value to the charge output line by the plurality of multiplication units the weight sum total value of which is the maximum value is used as the common time constant.

The common threshold value may be set on the basis of a duration of the input period.

Defining a sum total of absolute values of the weight values set in the plurality of multiplication units as a weight sum total value, the common threshold value may be set on the basis of a maximum value of the weight sum total value among the one or more multiply-accumulate devices.

The common charging mode may include charging in which a same charge signal is supplied during the common charging period. In this case, the charging unit may include a charging line that is connected to the accumulation unit and supplies the same charge signal to the accumulation unit during the common charging period.

The common charging mode may include charging in which a same charge signal is supplied during the common charging period. In this case, the charging unit may supply the same charge signal to the accumulation unit via the plurality of input lines during the common charging period.

The plurality of multiplication units may include at least one of a positive weight multiplication unit that generates a positive weight charge corresponding to a product value obtained by multiplying the input value by a positive weight value or a negative weight multiplication unit that generates a negative weight charge corresponding to a product value obtained by multiplying the input value by a negative weight value. In this case, the accumulation unit may include a positive charge accumulation unit capable of accumulating the positive weight charge generated by the positive weight multiplication unit and a negative charge accumulation unit capable of accumulating the negative weight charge generated by the negative weight multiplication unit. Moreover, the charging unit may charge the positive charge accumulation unit and the negative charge accumulation unit on the common charging mode. Moreover, the output unit may output the multiply-accumulate signal by performing threshold determination on each of the positive charge accumulation unit and the negative charge accumulation unit by using the common threshold value.

Defining a sum total of the positive weight values set in the plurality of multiplication units as a positive sum total value and a sum total of the absolute values of the negative weight values as a negative sum total value, the common charging mode may include charging based on a maximum value among the positive sum total values and the negative sum total values in the one or more multiply-accumulate devices.

Each of the one or more multiply-accumulate devices may include a positive charge output line and a negative charge output line. In this case, the positive charge multiplication unit may output the positive weight charge to the positive charge output line.

Moreover, the negative charge multiplication unit may output the negative weight charge to the negative charge output line. Moreover, assuming that the maximum value among the positive sum total values and the negative sum total values in the one or more multiply-accumulate devices is a maximum sum total value, that the positive weight charge or the negative weight charge related to the maximum sum total value is a maximum weight charge, and that the positive charge output line or the negative charge output line from which the maximum weight charge is output is a maximum charge output line, defining a time constant associated with the output of the maximum weight charge to the maximum charge output line as a common time constant, the common charging mode may include charging according to the common time constant.

Defining a sum total of the positive weight values set in the plurality of multiplication units as a positive sum total value and a sum total of the absolute values of the negative weight values as a negative sum total value, the common threshold value may be set on the basis of a maximum value among the positive sum total values and the negative sum total values in the one or more multiply-accumulate devices.

The positive weight value and the absolute value of the negative weight value may be fixed to a same value, set to any one of the plurality of values different from each other, or randomly set. In this case, in the one or more multiply-accumulate devices, a value obtained by adding the positive sum total value and the negative sum total value may be a common value.

The positive weight value and the absolute value of the negative weight value may be fixed to a same value, set to any one of the plurality of values different from each other, or randomly set. In this case, in the one or more multiply-accumulate devices, a value obtained by adding the positive sum total value and the negative sum total value may be a random value.

The common charging mode may include charging in which a same charge signal is supplied during the common charging period. In this case, the charging unit may include a charging line that is connected to the positive charge accumulation unit and the negative charge accumulation unit and supplies the same charge signal to the positive charge accumulation unit and the negative charge accumulation unit during the common charging period.

The common charging mode may include charging in which a same charge signal is supplied during the common charging period. In this case, the charging unit may supply the same charge signal to the positive charge accumulation unit and the negative charge accumulation unit via the plurality of input lines during the common charging period.

A multiply-accumulate system according to an embodiment of the present technology includes a plurality of input lines, one or more analog circuits, and a network circuit.

The one or more analog circuits includes a plurality of multiplication units, an accumulation unit, a charging unit, and an output unit.

The network circuit is configured by connecting the plurality of analog circuits.

Moreover, in the one or more analog circuits, the charging by the charging unit is performed on a common charging mode and a common threshold value is set as the predetermined threshold value.

### BRIEF DESCRIPTION OF DRAWINGS

FIG. 1 A schematic diagram showing a configuration example of an arithmetic apparatus according to an embodiment of the present technology.

FIG. 2A schematic diagram showing an example of an electrical signal to be input into an analog circuit.

FIG. 3A schematic diagram showing a specific configuration example of an arithmetic apparatus.

FIG. 4A schematic diagram showing a configuration example of a neuron circuit.

FIG. 5A schematic circuit diagram showing an example of an analog circuit of a PWM method.

FIG. 6A diagram for describing a calculation example of a multiply-accumulate signal by the analog circuit shown in FIG. 5.

FIG. 7A schematic diagram showing a calculation example of a multiply-accumulate signal showing the entire multiply-accumulate result.

FIG. 8 A schematic circuit diagram showing an example of an analog circuit according to a TACT method.

FIG. 9 A schematic graph for describing a potential of each output line at the end of the input period.

FIG. 10 A diagram showing a configuration example of an arithmetic apparatus including a plurality of analog circuits according to the PWM method.

FIG. 11 A diagram showing a configuration example of an arithmetic apparatus including a plurality of analog circuits according to the PWM method.

FIG. 12 A diagram showing a configuration example of an arithmetic apparatus including a plurality of analog circuits according to the TACT method.

FIG. 13 A diagram showing a configuration example of an arithmetic apparatus including a plurality of analog circuits according to the TACT method.

FIG. 14 A schematic view showing a configuration example of a neural network.

FIG. 15 A schematic circuit diagram showing another example of the analog circuit according to the PWM method.

FIG. 16 A schematic circuit diagram showing another example of the analog circuit according to the PWM method.

FIG. 17 A diagram for describing a calculation example of a multiply-accumulate signal according to the analog circuit shown in FIG. 16.

### MODE(S) FOR CARRYING OUT THE INVENTION

Hereinafter, embodiments according to the present technology will be described with reference to the drawings.

[Configuration of Arithmetic Apparatus]

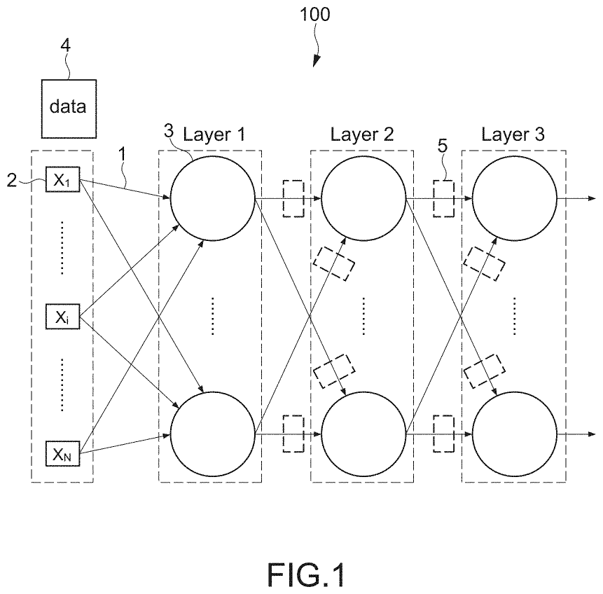

FIG. 1 is a schematic diagram showing a configuration example of an arithmetic apparatus according an embodiment of the present technology. An arithmetic apparatus 100 is an analog-type arithmetic apparatus that performs predetermined arithmetic processing including a multiply-accumulate operation. By using the arithmetic apparatus 100, for example, it is possible to perform arithmetic processing according to a mathematical model such as a neural network.

The arithmetic apparatus 100 includes a plurality of signal lines 1, a plurality of input units 2, and a plurality of analog circuits 3. Each of the signal lines 1 is a line that transmits a predetermined type of electrical signal. For example, an analog signal representing a signal value by using an analog amount such as a pulse timing and a pulse width is used as the electrical signal. The directions in which electrical signals are transmitted are schematically shown in FIG. 1 by means of arrows. In this embodiment, the analog circuits 3 corresponds to multiply-accumulate devices.

For example, the plurality of signal lines 1 is connected to one analog circuit 3. The signal line 1 that transmits an electrical signal to the analog circuit 3 is an input signal line, into which an electrical signal is input, for the analog circuit 3 to which that signal line 1 is connected. Moreover, the signal line 1 that transmits an electrical signal output from the analog circuit 3 is an output signal line, from which an electrical signal is output, for the analog circuit 3 to which that signal line 1 is connected. In this embodiment, the input signal line corresponds to an input line.

The plurality of input units 2 each generates a plurality of electrical signals corresponding to input data 4. The input data 4 is, for example, data to be processed using a neural network or the like implemented by the arithmetic apparatus 100. Therefore, it can also be said that the respective signal values of the plurality of electrical signals corresponding to the input data 4 are input values to the arithmetic apparatus 100.

For example, arbitrary data such as image data, audio data, and statistical data to be processed by the arithmetic apparatus 100 is used as the input data 4. For example, in a case where image data is used as the input data 4, an electrical signal using a pixel value (RGB value, luminance value, etc.) of each of pixels of the image data as a signal value is generated. In addition, an electrical signal corresponding to the input data 4 may be generated as appropriate in accordance with the type of the input data 4 and the contents of the processing performed by the arithmetic apparatus 100.

The analog circuit 3 is an analog-type circuit that performs a multiply-accumulate operation on the basis of an input electrical signal. The multiply-accumulate operation is, for example, an operation of adding up a plurality of product values obtained by multiplying a plurality of input values by weight values corresponding to input values. Therefore, it can also be said that the multiply-accumulate operation is processing of calculating a sum of the product values (hereinafter, referred to as a multiply-accumulate result).

As shown in FIG. 1, a plurality of input signal lines is connected to one analog circuit 3 and a plurality of electrical signals is provided thereto. The plurality of input signal lines and the analog circuit constitute a multiply-accumulate operation circuit according to this embodiment. Moreover, a plurality of electrical signals is input from each of the input signal lines, and a multiply-accumulate method according to this embodiment is accordingly performed by the multiply-accumulate operation circuit (analog circuit 3).

Hereinafter, it is assumed that the total number of electrical signals input into one analog circuit 3 is N. It should be noted that the number N of electrical signals to be input into each analog circuit 3 is set as appropriate for each circuit in accordance with, for example, the model, accuracy, and the like of arithmetic processing.

In the analog circuit 3, for example, a wᵢ*xᵢ is calculated which is a product value of a signal value xᵢ represented by an electrical signal input from an i-th input signal line and a weight value wᵢ corresponding to the signal value xᵢ. Here, i represents a natural number equal to or smaller than N (i=1, 2, . . . N). The operation of the product value is performed for each electrical signal (input signal line) and N product values are calculated. A value obtained by adding up the N product values is calculated as a multiply-accumulate result (sum of N product values). Therefore, the multiply-accumulate result calculated by one analog circuit 3 is expressed by the following expression.

$${\sum }_{i = 1}^{N} {w}_{i} \cdot {x}_{i} \qquad [ Formula 1 ]$$

The weight value wᵢ is set, for example, in the range of −α≤wᵢ≤+α. Here, α represents an arbitrary real value. Thus, the weight value wᵢ may include a positive weight value wᵢ, a negative weight value wᵢ, a zero weight value wᵢ, and the like. As described above, by setting the weight value wᵢ to be in a predetermined range, it is possible to avoid the situation where the multiply-accumulate result diverges.

Moreover, for example, the range in which the weight value wᵢ is set may be normalized. In this case, the weight value wᵢ is set to be in a range of −1≤wᵢ≤1. Accordingly, for example, the maximum value, the minimum value, and the like of the multiply-accumulate result can be adjusted, and the multiply-accumulate operation can be performed with a desired accuracy.

In a neural network or the like, a method called binary connect, which sets the weight value wᵢ to be either +α or −α, can be used. The binary connect is used in various fields such as image recognition using a deep neural network (multi-layer neural network). The use of the binary connect can simplify the setting of the weight value wᵢ without deteriorating the recognition accuracy and the like. In the binary connect, the positive weight value and the absolute value of the negative weight value are fixed to the same value.

As described above, in the binary connect, the weight value wᵢ is binarized into a binary value (±α). Thus, a desired weight value wᵢ can be easily set by changing the weight value wᵢ to be positive or negative, for example. Alternatively, the binarized weight value wᵢ may be normalized and the weight value wᵢ may be set to ±1.

Moreover, the weight value wi may be multivalued. In this case, the weight value wi is set by selecting from a plurality of discrete weight value candidates. Examples of the weight value candidates include (−3, −2, −1, 0, 1, 2, 3) and (1, 2, 5, 10). Moreover, standardized weight value candidates (−1, −0.5, 0, 0.5, 1) or the like may be used. A value is selected from among these weight value candidates and is set as the weight value wi. The number of weight value candidates, the method of setting the candidate values, and the like are not limited. By multivaluing the weight value wi, it is possible to construct a neural network or the like with high versatility, for example.

In addition, the setting range, the setting value, and the like of the weight value wᵢ are not limited, and may be set as appropriate such that desired processing accuracy is realized, for example. For example, the weight value wᵢ may be randomly set.

The signal values xᵢ are, for example, electrical signals output from the input units 2 and multiply-accumulate results output from the analog circuits 3. In this way, it can also be said that the input units 2 and the analog circuits 3 function as signal sources for outputting the signal values xᵢ.

In the example shown in FIG. 1, a single electrical signal (single signal value xᵢ) is output from one signal source (input unit 2, analog circuit 3). Therefore, the same electrical signal is input into each of the plurality of signal lines 1 connected to an output side of the one signal source. Moreover, one signal source and the analog circuit 3 into which the electrical signal output from the signal source is input are connected to each other by a single input signal line.

Therefore, for example, M input signal lines are connected to the analog circuit 3 connected to M signal sources in the arithmetic apparatus 100 shown in FIG. 1. In this case, the total number N of electrical signals input into the analog circuits 3 is N=M. It should be noted that a configuration in which a pair of electrical signals corresponding to positive and negative values (pair of signal values xᵢ⁺, xᵢ⁻) is output from one signal source is possible.

As shown in FIG. 1, the arithmetic apparatus 100 has a layered structure in which the plurality of analog circuits 3 is provided in each of a plurality of layers. By configuring the layer structure of the analog circuits 3, a multi-layer perceptron-type neural network or the like, for example, is constructed. The number of analog circuits provided in each layer, the number of layers, and the like are designed as appropriate such that desired processing can be performed, for example. Hereinafter, the number of analog circuits 3 provided in a j-th layer will be sometimes referred to as Nⱼ.

For example, N electrical signals generated by N input units 2 are input into each analog circuit 3 provided in a layer of a first stage (lowest layer). The analog circuits 3 of the first stage calculate multiply-accumulate results related to the signal values xᵢ of the input data, and output the calculated multiply-accumulate results to the analog circuits 3 provided in a next layer (second stage) after the non-linear conversion processing.

N₁ electrical signals representing the respective multiply-accumulate results calculated in the first stage are input into the respective analog circuits 3 provided in a second layer (upper layer). Therefore, as viewed from the analog circuits 3 of the second stage, the non-linear conversion processing results of the respective multiply-accumulate results calculated in the first stage are the signal values xᵢ of the electrical signals. The analog circuits 3 of the second stage calculate the multiply-accumulate results of the signal values xᵢ output from the first stage, and output the calculated multiply-accumulate results to the analog circuits 3 of the upper layer.

In this way, in the arithmetic apparatus 100, the multiply-accumulate results of the analog circuits 3 in the upper layer are calculated on the basis of the multiply-accumulate results calculated by the analog circuits 3 in the lower layer. Such processing is performed multiple times, and the processing results are output from the analog circuits 3 included in the top layer (the layer of the third stage in FIG. 1). Accordingly, for example, processing such as image recognition of determining that the object is a cat on the basis of image data (input data 4) obtained by imaging the cat can be performed.

As described above, a desired network circuit can be configured by connecting the plurality of analog circuits 3 as appropriate. The network circuit functions as a data flow processing system that performs arithmetic processing by, for example, causing signals to pass therethrough. In the network circuit, various processing functions can be realized by setting, for example, a weight value (synapse connection) as appropriate. With this network circuit, the multiply-accumulate system according to this embodiment is constructed.

It should be noted that the method of connecting the analog circuits 3 to each other and the like are not limited, and, for example, the plurality of analog circuits 3 may be connected to each other as appropriate such that desired processing can be performed. For example, the present technology can be applied even in a case where the analog circuits 3 are connected to each other so as to configure another structure different from the layered structure.

In the above description, the configuration in which the multiply-accumulate results calculated in the lower layer are input into the upper layer as they are has been described. The present technology is not limited thereto, and, for example, conversion processing or the like may be performed on the multiply-accumulate results. For example, in the neural network model, processing of, for example, performing non-linear conversion on the multiply-accumulate result of each analog circuit 3 by using an activation function and inputting the conversion results to the upper layer is performed.

In the arithmetic apparatus 100, a function circuit 5 or the like that performs non-linear conversion using an activation function on the electrical signal, for example, is used. The function circuit 5 is, for example, a circuit that is provided between a lower layer and an upper layer and that converts a signal value of an input electrical signal as appropriate and outputs an electrical signal according to the conversion result. The function circuit 5 is provided for each of the signal lines 1, for example. The number of function circuits 5, the arrangement of the function circuits 5, and the like are set as appropriate in accordance with, for example, the mathematical model implemented in the arithmetic apparatus 100.

For example, a ReLU function (ramp function) or the like is used as the activation function. The ReLU function outputs the signal value xᵢ as it is in a case where the signal value xᵢ is 0 or more, for example, and outputs 0 otherwise. For example, the function circuit 5 that implements the ReLU function is connected to each of the signal lines 1 as appropriate. Accordingly, it is possible to realize the processing of the arithmetic apparatus 100.

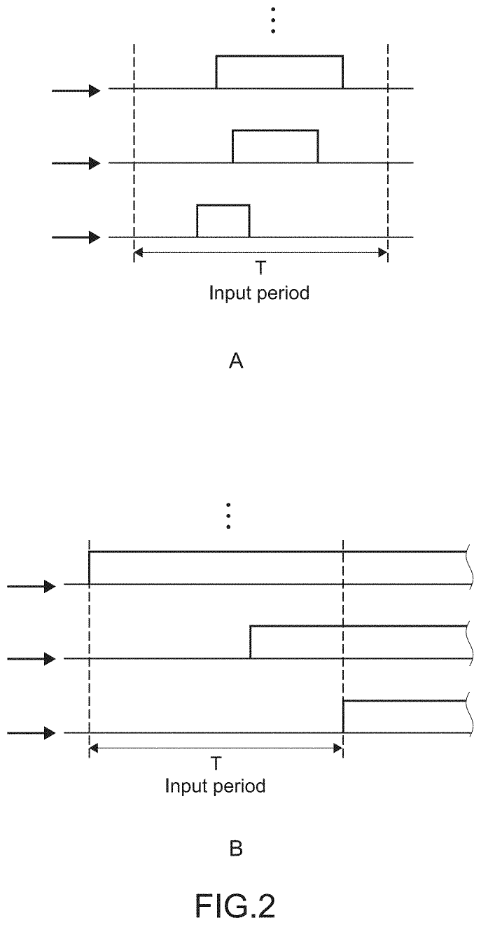

FIG. 2 is a schematic diagram showing an example of the electrical signal input into the analog circuit 3. In each of FIGS. 2A and B, a graph representing a waveform of a plurality of electrical signals is schematically shown. The horizontal axis of the graph indicates the time axis and the vertical axis indicates the voltage of the electrical signal.

An exemplary waveform of an electrical signal according to a pulse width modulation (PWM) method is shown in FIG. 2A. The PWM method is a method of representing a signal value xᵢ by using a pulse width τᵢ of a pulse waveform, for example. That is, in the PWM method, the pulse width τᵢ of the electrical signal is a length depending on the signal value xᵢ.

Typically, the longer the pulse width τᵢ, the higher the signal value xᵢ.

Moreover, the electrical signal is input into the analog circuit 3 within a predetermined input period T. More specifically, the respective electrical signals are input into the analog circuits 3 such that the pulse waveforms of the electrical signals fall in the input period T. Therefore, the maximum value of the pulse width of the electrical signal is similar to the input period T. It should be noted that the timing at which each pulse waveform (electrical signal) are input and the like are not limited as long as the pulse waveform falls in the input period T.

In the PWM method, for example, a duty ratio Rᵢ (=Tᵢ/T) of the pulse width τᵢ to the input period T can be used to normalize the signal value xᵢ. That is, the normalized signal value xᵢ is represented as the signal value xᵢ=Rᵢ. It should be noted that the method of associating the signal value xᵢ with the pulse width τᵢ is not limited and, for example, the pulse width τᵢ representing the signal value xᵢ may be set as appropriate such that the calculation processing or the like can be performed with a desired accuracy.

In a case where the electrical signal according to the PWM method is used, a time-axis analog multiply-accumulate operation using the analog circuit 3 according to the PWM method can be performed.

In FIG. 2B, an exemplary waveform of the electrical signal of a spike timing method (hereinafter, referred to as TACT method) is shown. The TACT method is a method of representing a signal value xᵢ by using the rising timing of the pulse, for example. For example, a pulse is input at a timing corresponding to the input value by using a predetermined timing as a reference.

The electrical signal is input into the analog circuit 3 within the predetermined input period T. The signal value xᵢ is represented by the input timing of the pulse within this input period T. For example, a largest signal value xᵢ is represented by a pulse input at the same time as the start of the input period T. A smallest signal value xᵢ is represented by a pulse input at the same time as the end of the input period T.

It can also be said that the signal value xi is represented by the duration from the input timing of the pulse to the end timing of the input period T. For example, the largest signal value xᵢ is represented by a pulse whose duration from the input timing of the pulse to the end timing of the input period T is equal to the input period T. The smallest signal value xᵢ is represented by a pulse whose duration from the input timing of the pulse to the end timing of the input period T is 0.

It should be noted that in the FIG. 2B, a continuous pulse signal that rises to a timing corresponding to the input value and keeps the ON level until the multiply-accumulate result is obtained is used as the electrical signal according to the TACT method. The present technology is not limited thereto, and a rectangular pulse or the like having a predetermined pulse width may be used as the electrical signal according to the TACT method.

In a case where the electrical signal according to the TACT method is used, a time-axis analog multiply-accumulate operation using the analog circuit 3 according to the TACT method can be performed.

As illustrated in FIGS. 2A and B, a pulse signal whose duration of the ON time with respect to the input period T corresponds to the input value can be used as the electrical signal corresponding to the input value. It should be noted that hereinafter, the description will be made assuming that the signal value xᵢ represented by each electrical signal is a variable of 0 or more and 1 or less.

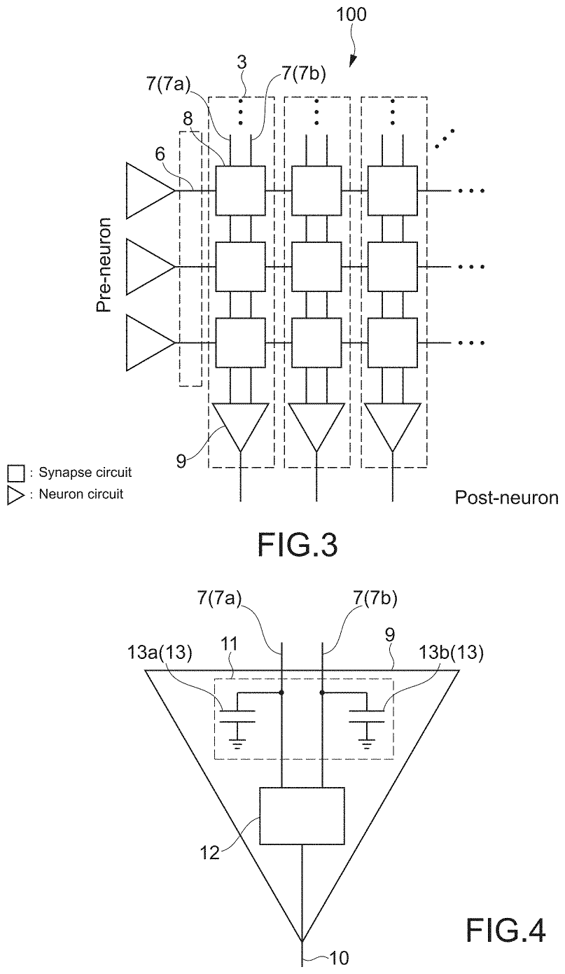

FIG. 3 is a schematic diagram showing a specific configuration example of the arithmetic apparatus 100. FIG. 3 is an arrangement example of circuits for realizing the arithmetic apparatus 100 shown in FIG. 1, for example, and schematically shows the plurality of analog circuits 3 provided in one layer of the arithmetic apparatus 100.

The analog circuits 3 each include a pair of output lines 7, a plurality of synapse circuits 8, and a neuron circuit 9. As shown in FIG. 3, one analog circuit 3 is configured to extend in a predetermined direction (vertical direction in the figure). A plurality of such analog circuits 3 extending in the vertical direction are arranged side by side in the horizontal direction, to thereby form one layer.

Hereinafter, it is assumed that the analog circuit 3 disposed on the leftmost side in the figure is a first analog circuit 3. Moreover, the direction in which the analog circuits 3 extend will be sometimes referred to as an extension direction.

The pair of output lines 7 is spaced apart from each other along the extension direction. The pair of output lines 7 includes a positive charge output line 7a and a negative charge output line 7b. Each of the positive charge output line 7a and the negative charge output line 7b is connected to the neuron circuit 9 via the plurality of synapse circuits 8.

The synapse circuit 8 calculates a product value (wᵢ*xᵢ) of the signal value xᵢ represented by the electrical signal and the weight value wᵢ.

Specifically, a charge (current) corresponding to the product value is output to either the positive charge output line 7a or the negative charge output line 7b.

As will be described later, either the positive weight value wᵢ⁺ or the negative weight value is set to the synapse circuit 8. For example, a positive weight charge corresponding to the product value of the positive weight value wᵢ⁺ is output to the positive charge output line 7a. Moreover, for example, a negative weight charge corresponding to the product value of the negative weight value wᵢ⁻ is output to the negative charge output line 7b.

It should be noted that in the synapse circuit 8, a charge with the same sign (e.g., a positive charge) is output as the charge corresponding to the product value irrespective of whether the weight value wᵢ is positive or negative. That is, the positive weight charge and the negative weight charge become charges with the same sign.

In this way, the synapse circuits 8 are each configured to output the charge corresponding to the multiplication result to the different output line 7a or 7b in accordance with the sign of the weight value wi. A specific configuration of the synapse circuit 8 will be described later in detail. In this embodiment, the plurality of synapse circuits 8 functions as a plurality of multiplication units that generates a charge corresponding to a product value obtained by multiplying an input value by a weight value on the basis of an electrical signal input into each of the plurality of input lines.

In this embodiment, the single input signal line 6 and the pair of output lines 7 are connected to the single synapse circuit 8. That is, a single electrical signal is input into the single synapse circuit 8 and a charge corresponding to the product value calculated on the basis of the input electrical signal is output to either the output line 7a or 7b. Thus, the synapse circuit 8 is a one-input two-output circuit connected to the single input signal line 6 and the pair of output lines 7 (positive charge output line 7a and the negative charge output line 7b).

In one analog circuit 3, the plurality of synapse circuits 8 is arranged along the pair of output lines 7. Each synapse circuits 8 is connected in parallel to the positive charge output line 7a (negative charge output line 7b). Hereinafter, it is assumed that the synapse circuit 8 disposed on a most downstream side (side connected to the neuron circuit 9) is a first synapse circuit.

As shown in FIG. 3, the plurality of input signal lines 6 is wired so as to intersect with the pair of output lines 7 of each of the plurality of analog circuits 3. Typically, the input signal line 6 is provided to be orthogonal to each output line 7. That is, the arithmetic apparatus 100 has a crossbar configuration in which the input signal lines 6 and the output lines 7 cross each other. With the crossbar configuration, the analog circuits 3 and the like, for example, can be integrated at high density.

Moreover, in the arithmetic apparatus 100, j-th synapse circuits 8 included in the respective analog circuits 3 are connected in parallel to a j-th input signal line 6. Therefore, similar electrical signals are input into the synapse circuits 8 connected to the same input signal line 6. Accordingly, a configuration in which one signal source included in the lower layer is connected to a plurality of analog circuits 3 included in the upper layer can be implemented.

It should be noted that in the example shown in FIG. 3, the analog circuit 3 (pre-neuron) included in the lower layer is schematically shown as a signal source that inputs an electrical signal into each of the input signal lines 6. The present technology is not limited thereto, and, for example, the crossbar configuration can be used also in a case where the input unit 2 is used as the signal source.

As described above, in the arithmetic apparatus 100, the plurality of analog circuits 3 is connected in parallel to each of the plurality of input signal lines 6. Accordingly, for example, it is possible to input an electrical signal in parallel into each analog circuit 3 (each synapse circuit 8) and to achieve arithmetic processing at high speed. As a result, it is possible to exhibit excellent operation performance.

The neuron circuit 9 calculates a multiply-accumulate result shown in the expression (Formula 1) on the basis of the product values calculated by the synapse circuits 8. Specifically, the neuron circuit 9 outputs an electrical signal representing the multiply-accumulate result (multiply-accumulate signal) on the basis of charges input via the pair of output lines 7.

FIG. 4 is a schematic diagram showing a configuration example of the neuron circuit 9. The neuron circuit 9 includes an accumulation unit 11 and a signal output unit 12. FIG. 4 shows a two-input one-output neuron circuit 9 connected to a pair of output lines 7 and a single output signal line 10. It should be noted that a two-input two-output circuit or the like can be used as the neuron circuit 9 in some cases.

The accumulation unit 11 accumulates charges output to the pair of output lines 7 by the plurality of synapse circuits 8. The accumulation unit 11 includes two capacitors 13a and 13b. The capacitor 13a is connected between the positive charge output line 7a and the GND. Moreover, the capacitor 13b is connected between the negative charge output line 7b and the GND. Therefore, charges flowing in from the positive charge output line 7a and the negative charge output line 7b are respectively accumulated in the capacitors 13a and 13b.

For example, when the input period T of the electrical signal has elapsed, the charges accumulated in the capacitor 13a are a sum total σ⁺ of positive weight charges each corresponding to the product value of the positive weight value wᵢ⁺. Also, the charges accumulated in the capacitor 13b are a sum total σ⁻ of negative weight charges corresponding to the product value of the negative weight value wᵢ⁻.

For example, in a case where the positive weight charges are accumulated in the capacitor 13a, the potential of the positive charge output line 7a with reference to the GND increases. Therefore, the potential of the positive charge output line 7a is a value depending on the sum total σ⁺ of the charges each corresponding to the product value of the positive weight value wᵢ⁺+. It should be noted that the potential of the positive charge output line 7a corresponds to the voltage retained by the capacitor 13a.

Similarly, in a case where the negative weight charges are accumulated in the capacitor 13b, the potential of the negative charge output line 7b with reference to the GND increases. Therefore, the potential of the negative charge output line 7b is a value depending on the sum total σ⁻ of the charges each corresponding to the product value of the negative weight value wᵢ⁻. It should be noted that the potential of the negative charge output line 7b corresponds to the voltage retained by the capacitor 13b.

The signal output unit 12 outputs a multiply-accumulate signal representing a sum of the product values (wᵢ⁺*xᵢ) on the basis of the charges accumulated in the accumulation unit 11. The multiply-accumulate signal is, for example, a signal representing a total multiply-accumulate result, which is a sum of product values of all positive and negative weight values wᵢ and signal values xᵢ. For example, the multiply-accumulate result represented by the expression (Formula 1) can be written as follows.

$${\sum }_{i = 1}^{N} {w}_{i} {x}_{i} = {\sum }_{i = 1}^{{N}^{+}} {w}_{i}^{+} {x}_{i} - {\sum }_{i = 1}^{{N}^{-}} \vert {w}_{i}^{-} \vert {x}_{i} \qquad [ Formula 2 ]$$

Here, N⁺ and N⁻ are the total number of positive weight values wᵢ⁺ and the total number of negative weight values wᵢ⁻, respectively. As shown in the expression (Formula 2), the total multiply-accumulate result can be calculated as a difference between a multiply-accumulate result of positive weight charges, which is a sum total of product values (wᵢ⁺*xᵢ) of the positive weight values wᵢ⁺, and a multiply-accumulate result of negative weight charges, which is a sum total of product values (|wᵢ⁻|*xᵢ) of the negative weight values wᵢ⁻.

In the example shown in FIG. 4, the signal output unit 12 generates one signal representing the total multiply-accumulate result, for example, as the multiply-accumulate signal. Specifically, by referring to the charges accumulated in the accumulation unit 11 (capacitors 13a and 13b) as appropriate, a positive multiply-accumulate result and a negative multiply-accumulate result are calculated, and the total multiply-accumulate result is calculated on the basis of the difference therebetween. Moreover, for example, two signals of a positive multiply-accumulate signal and a negative multiply-accumulate signal respectively representing the positive and negative multiply-accumulate results may be generated as the multiply-accumulate signals.

The method of referring to the charges accumulated in the accumulation unit 11 is not limited. As an example, a method of detecting charges accumulated in one capacitor 13 will be described. In a case where the electrical signal according to the PWM method illustrated in FIG. 2A is used, the charges each corresponding to the product value are accumulated in the capacitor 13 within the input period T. That is, the accumulation of charges each corresponding to the product value does not occur before and after the input period T.

For example, after the input period T ends, the capacitor 13 is charged at a predetermined charging speed. At this time, a comparator or the like is used to detect a timing at which the potential of the output line to which the capacitor 13 is connected reaches a predetermined threshold potential. For example, as more charges are accumulated at the time of starting charging, the timing at which the potential reaches the threshold potential becomes earlier. Therefore, the charges (multiply-accumulate result) accumulated within the input period T can be represented on the basis of the timing. It should be noted that the charging speed can be expressed by, for example, a charge amount per unit time, and can also be referred to as a charging rate.

It should be noted that this threshold determination corresponds to increasing the voltage retained by the capacitor 13 by charging and detecting the timing at which the threshold voltage is reached.

In a case where the electrical signal according to the TACT method illustrated in FIG. 2B is used, charges are accumulated in the capacitor 13 because the ON level is maintained also after the input period T ends. For this charge accumulation, the timing at which the potential of the output line to which the capacitor 13 is connected reaches the predetermined threshold potential is detected by using the comparator or the like. For example, as more charges are accumulated at the end of input period T, the timing at which the potential reaches the threshold potential becomes earlier. Therefore, the charges (multiply-accumulate result) accumulated within the input period T can be represented on the basis of the timing. 4

It should be noted that this threshold determination corresponds to detecting the timing at which the voltage retained by the capacitor 13 reaches the threshold voltage.

For example, by performing such threshold determination, a timing to represent the multiply-accumulate result is detected. The multiply-accumulate signal of positive weight charges, the multiply-accumulate signal of negative weight charges, or the total multiply-accumulate signal is generated as appropriate on the basis of the detection result. In addition, each multiply-accumulate result may be calculated by directly reading the potential of the capacitor 13 when the input period T ends, for example.

It should be noted that the voltage depending on the accumulated positive weight charges and the voltage depending on the accumulated negative weight charges may be each amplified in order to generate the multiply-accumulate signal. Moreover, the multiply-accumulate signal may be generated by amplifying the differential voltage between the voltage depending on the accumulated positive weight charges and the voltage depending on the accumulated negative weight charges. For example, a differential amplifier or the like having an arbitrary configuration may be provided in the neuron circuit 9.

In this embodiment, the neuron circuit 9 functions as an output unit that accumulates charges corresponding to the product values generated by the plurality of multiplication units and outputs a multiply-accumulate signal representing a sum of the product values on the basis of the accumulated charges.

Moreover, the capacitor 13a and the capacitor 13b functions as a positive charge accumulation unit and a negative charge accumulation unit. The neuron circuit 9 accumulates at least one of a positive weight charge generated by a positive weight multiplication unit and a negative weight charge generated by a negative weight multiplication unit, to thereby output a multiply-accumulate signal.

Moreover, as it will be described in detail later, in this embodiment, the charging unit is configured, and the accumulation unit 11 (capacitor 13) in which the charge corresponding to the product value is accumulated is charged after the input period T. It should be noted that the charging according to the present technology includes accumulating the charge in the capacitor 13 by the pulse signal whose ON level is kept in a case where the electrical signal according to the TACT method is used.

The signal output unit 12 functions as an output unit for outputting a multiply-accumulate signal representing the sum of the product values by performing threshold determination using a predetermined threshold value on the voltage retained by the accumulation unit 11 after the charging unit starts charging. The signal output unit 12 outputs the multiply-accumulate signal by performing the threshold determination for each of the positive charge accumulation unit and the negative charge accumulation unit.

[Analog Circuit According to PWM Method]

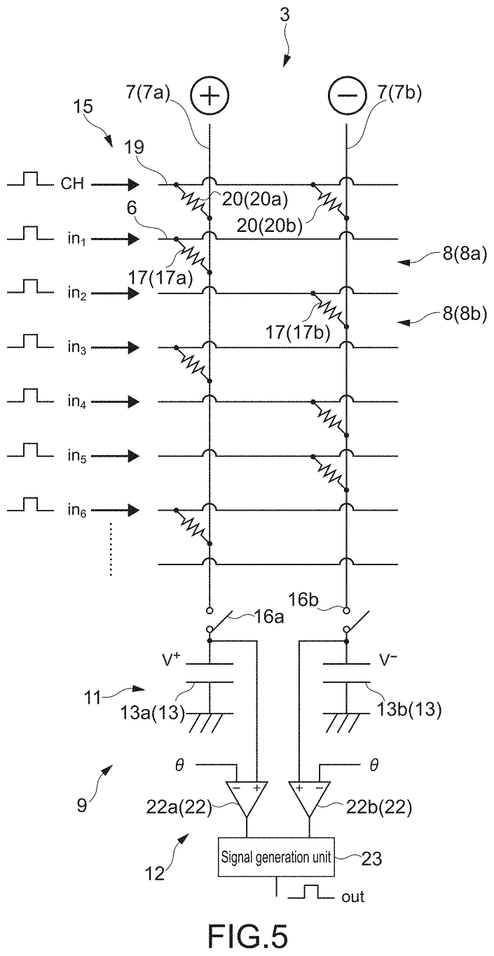

FIG. 5 is a schematic circuit diagram showing an example of the analog circuit according to this embodiment. In FIG. 5, an example of the analog circuit 3 according to the PWM method is shown. The analog circuit 3 is provided extending in a direction orthogonal to the plurality of input signal lines 6. That is, in the example shown in FIG. 5, the crossbar configuration is employed.

The analog circuit 3 includes the pair of output lines (positive charge output line 7a and negative charge output line 7b), a plurality of synapse circuits (plurality of multiplication units) 8, a neuron circuit 9, and a charging unit 15. In the example shown in FIG. 5, the neuron circuit 9 includes the accumulation unit 11, a signal output unit 12, and switches 16a and 16b.

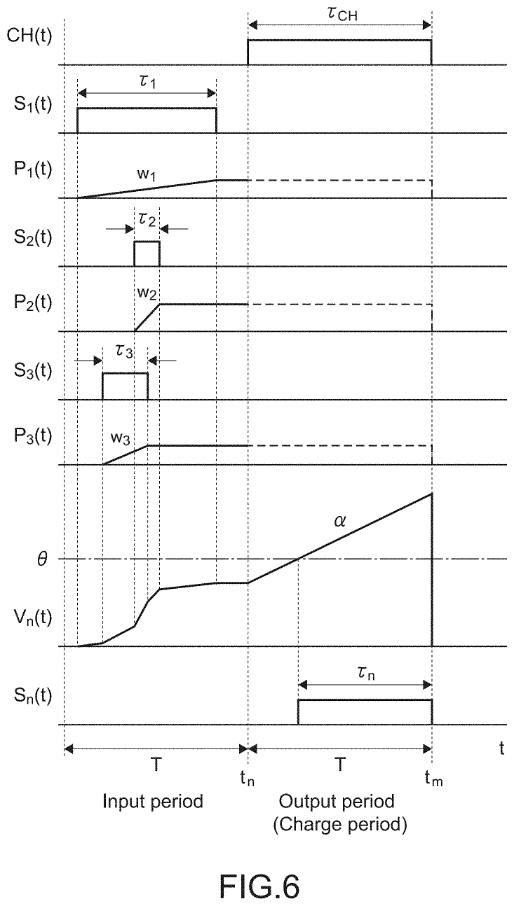

Pulse signals (PWM signals) each having a pulse width corresponding to the signal value xᵢ are input into the plurality of input signal lines 6 as input signals in₁ to in₆. In the example shown in FIG. 5, six input signal lines 6 are shown, though the number of input signal lines 6 is not limited. The input signals in₁ to in₆ are input within the input period T having a predetermined duration (see FIG. 6).

The positive charge output line 7a outputs the positive weight charges corresponding to the product values (wᵢ+*xᵢ) each obtained by multiplying the signal value xᵢ by the positive weight value wᵢ⁺. The negative charge output line 7b outputs the negative weight charges corresponding to the product values (|wᵢ⁻|*xᵢ) each obtained by multiplying the signal value xᵢ by the negative weight value wᵢ⁻. In this embodiment, the pair of output lines 7 corresponds to one or more output lines.

The plurality of synapse circuits 8 is provided to be associated with the plurality of input signal lines 6, respectively. In this embodiment, one synapse circuit 8 is provided in one input signal line 6. Each of the plurality of synapse circuits 8 includes a resistor 17 that is connected between the corresponding input signal line 6 of the plurality of input signal lines 6 and any one of the positive charge output line 7a or the negative charge output line 7b. This resistor 17 may have a non-linear characteristic and may have a function of preventing backflow of current. A charge corresponding to the product value (wᵢ+*xᵢ) (or (|wᵢ⁻|*xᵢ)) is output to the output line 7a (or 7b) to which the resistor 17 is connected.

For example, in order to multiply the signal value xᵢ by the positive weight value wᵢ⁺ in each synapse circuit 8, the resistor 17 is connected between the input signal line 6 and the positive charge output line 7a and the positive charge output line 7a is made to output a positive weight charge. In the example shown in FIG. 5, the synapse circuit 8 into which the input signal in₁, in₃, in₆ is input is a synapse circuit 8a configured as the positive weight multiplication unit that generates a positive weight charge. It can also be said that the synapse circuit 8a is a multiplication unit in which a positive weight is set.

In order to multiply the signal value xᵢ by the negative weight value in each synapse circuit 8, the resistor 17 is connected between the input signal line 6 and the negative charge output line 7b and the negative charge output line 7b is made to output a negative weight charge. In the example shown in FIG. 5, the synapse circuit 8 into which the input signal in₂, in₄, in₅ is input is a synapse circuit 8b configured as the negative weight multiplication unit that generates a negative weight charge. It can also be said that the synapse circuit 8b is a multiplication unit in which a negative weight is set.

Hereinafter, the synapse circuits 8a and 8b will be sometimes referred to as a positive weight multiplication unit 8a and a negative weight multiplication unit 8b. Moreover, the resistor 17 connected between the input signal line 6 and the positive charge output line 7a will be sometimes referred to as a positive resistor 17a. Moreover, the resistor 17 connected between the input signal line 6 and the negative charge output line 7b will be sometimes referred to as a negative resistor 17b.

It should be noted that a resistor having a resistance value corresponding to the weight value wᵢ to be set is used as the resistor 17. That is, the resistor 17 functions as an element that defines the weight value wᵢ in the arithmetic apparatus 100 that performs multiply-accumulate operations at the analog circuits 3.

For example, a fixed resistor element, a variable resistor element, a MOS transistor that operates in a sub-threshold region, or the like is used as the resistor 17. By using a MOS transistor that operates in the sub-threshold region as the resistor 17, for example, it is possible to reduce the power consumption. As a matter of course, another arbitrary resistor may be used.

The accumulation unit 11 accumulates charges corresponding to the product values (wᵢ*xᵢ) generated by the plurality of synapse circuits 8. In this embodiment, two capacitors 13a and 13b are provided as the accumulation unit 11.

The capacitor 13a is connected to the positive charge output line 7a via the switch 16a to accumulate the positive weight charges generated by the synapse circuits 8a. The capacitor 13b is connected to the negative charge output line 7b via the switch 16b to accumulate the negative weight charges generated by the synapse circuits 8b.

The charging unit 15 charges the accumulation unit 11 in which a sum of charges corresponding to the product values (wᵢ*xᵢ) is accumulated. In this embodiment, the charging unit 15 includes a signal source (not shown), a charging line 19, and two resistors 20.

The charging line 19 is arranged in parallel with the input signal line 6. A resistor 20a of the two resistors 20 is connected between the charging line 19 and the positive charge output line 7a. Another resistor 20b is connected between the charging line 19 and the negative charge output line 7b. Therefore, the charging line 19 is connected to the capacitor 13a via the resistor 20a. Moreover, the charging line 19 is connected to the capacitor 13a via the resistor 20b.

The resistors 20a and 20b having the same resistance value are used. Although the same resistors are typically used, different types of resistors having the same resistance value may be used. The specific configurations of the resistors 20a and 20b are not limited, various configurations may be used as in the resistor 17. Moreover, the same resistors as the resistor 17 or resistors different from the resistor 17 may be used as the resistors 20a and 20b.

The charging is performed after the input period T ends. In this embodiment, a charge signal CH is input via the charging line 19 after the input period T ends. That is, the same charge signal CH is supplied to the capacitors 13a and 13b from the charging line 19. Thus, charges based on the high-level value of the charge signal CH and the resistance values of the resistors 20a and 20b are accumulated in the capacitors 13a and 13b.

Since the resistance values of the resistors 20a and 20b are values equal to each other, the capacitors 13a and 13b are charged at the same charging speed. By the charging by the charging unit 15, the potential V⁺ of the positive charge output line 7a (the voltage retained by the capacitor 13a) and the potential V⁻ of the negative charge output line 7b (the voltage retained by the capacitor 13b) are each increased.

After the charging unit 15 starts charging, the signal output unit 12 performs threshold determination on the voltage retained by the accumulation unit 11 on the basis of a predetermined threshold value, to thereby output a multiply-accumulate signal representing a sum of the product values (wᵢ*xᵢ). In this embodiment, two comparators 22a and 22b and a signal generation unit 23 are provided as the signal output unit 12.

The comparator 22a detects a timing at which the voltage retained by the capacitor 13a exceeds a predetermined threshold value. It should be noted that the magnitude of the voltage retained by the capacitor 13a is determined by the total amount of positive weight charge accumulated in the capacitor 13a and the charge amount (charging speed x time).

The comparator 22b detects a timing at which the voltage retained by the capacitor 13b exceeds a predetermined threshold value. It should be noted that the magnitude of the voltage retained by the capacitor 13b is determined by the total amount of negative weight charge accumulated in the capacitor 13b and the charge amount (charging speed x time).

It should be noted that in this embodiment, a multiply-accumulate signal is output by performing threshold determination on each of the capacitors 13a and 13b with a common threshold value θ. Accordingly, it is possible to improve the efficiency and speed of the operation. As a matter of course, also in a case where threshold values different from each other are used, the multiply-accumulate operation is possible.

The signal generation unit 23 outputs a multiply-accumulate signal representing a sum of the product values (wᵢ*xᵢ) on the basis of the timing detected by the comparator 22a and the timing detected by the comparator 22b. In other words, the signal generation unit 23 outputs a multiply-accumulate signal on the basis of a timing at which the voltage retained by the capacitor 13a reaches the threshold value θ and a timing at which the voltage retained by the capacitor 13b reaches the threshold value θ.

In this embodiment, a PMW signal, which is a pulse signal the pulse width of which has been modulated, is output as the multiply-accumulate signal. The specific circuit configuration and the like of the signal generation unit 23 are not limited and may be arbitrarily designed.

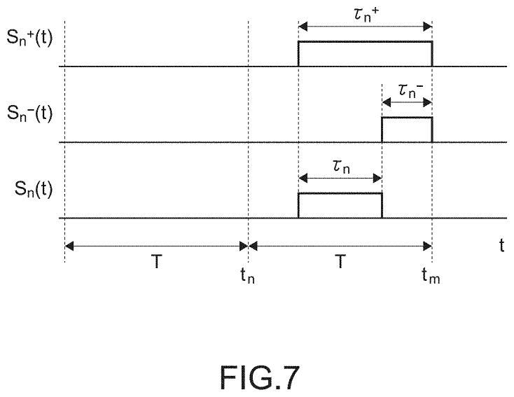

FIGS. 6 and 7 are diagrams for describing a calculation example of the multiply-accumulate signal by the analog circuit 3 shown in FIG. 5. In this embodiment, a signal representing the total multiply-accumulate result including the positive and negative values is calculated on the basis of the multiply-accumulate result of positive weight charges based on the positive weight charges accumulated in the capacitor 13a and the multiply-accumulate result of negative weight charges based on the negative weight charges accumulated in the capacitor 13b.

The calculation of the multiply-accumulate result of the positive weight charges and the calculation of the multiply-accumulate result of the negative weight charges are the same processing. First, a method (multiply-accumulate method) of calculating the multiply-accumulate result on the basis of the charges accumulated in the capacitor 13 without discrimination between positive and negative values will be described with reference to FIG. 6.

The parameters described in FIG. 6 will be described. “t” represents time. “T” represents each of the input period and the output period. “tₙ” represents an end timing of the input period T and “tₘ” represents an end timing of the output period T.

In this embodiment, the duration of the input period T and the duration of the output period T are set to be equal to each other. Moreover, the output period T is started from an end timing tₙ of the input period T. Therefore, the end timing tₙ of the input period T corresponds to the start timing of the output period T.

Moreover, in this embodiment, the charging unit 15 performs charging in the output period T after the input period T. Thus, the output period T corresponds to the charging period.

“θ” represents a common threshold value used for threshold determination performed by the signal output unit 12 (comparator 22 ).

“Sᵢ(t)” represents an input signal (PWM signal) input into an i-th input signal line 6. “τᵢ” represents the pulse width of the input signal Sᵢ(t). “Pᵢ(t)” represents an amount of change of an internal state (potential) in each synapse circuit 8 shown in FIG. 5. “wᵢ” represents a weight value and is defined by the resistance value of the resistor 17 shown in FIG. 5.

“Vₙ(t)” represents a sum total of “Pᵢ(t)” and corresponds to the total amount of charge accumulated in the capacitor 13. “Sₙ(t)” represents a multiply-accumulate signal (PWM signal) representing the multiply-accumulate result. “τₙ” represents the pulse width of the multiply-accumulate signal to be output. Specifically, “Tₙ” represents a value corresponding to the duration from the timing at which the voltage retained by the capacitor 13 exceeds the threshold value θ in the output period T to the end timing tₘ of the output period T.

“CH(t)” is a charge signal input into the charging line 19 in the output period T that is the charging period. As shown in FIG. 6, in this embodiment, the pulse signal that becomes ON level during the output period T is input as the charge signal. Therefore, the pulse width τ_{CH} of the charge signal is equal to the pulse width of the charge signal in the output period T.

In this example, the switches 16a and 16b are provided, and, in particular, it is possible to improve the reduction of the power consumption by disconnecting the output line through this switch.

Here, as shown in the following expression, the input value (signal value) xᵢ is given by the duty ratio Rᵢ (=τ/T) of the pulse width τᵢ of the input signal Sᵢ(t) to the input period T.

$${x}_{i} = {R}_{i} ( = \frac{{τ}_{i}}{T} ) \qquad [ Formula 3 ]$$

The synapse circuit 8 shown in FIG. 5 generates the charge corresponding to the product value obtained by multiplying the signal value xᵢ by the weight value wᵢ. Specifically, the resistance of the resistor 17 increases the internal state (potential) at a constant slope wᵢ.

The amount of change Pᵢ(tₙ) of the internal potential of each synapse circuit 8 at the end timing tₙ of the input period T is given by the following expression. It should be noted that the high-level value of the input-signal Sᵢ(t) is set to 1.

Pᵢ(tₙ)=wᵢRᵢT=wᵢxᵢT [Formula 4]

The total amount Vₙ(tₙ) of charge accumulated in the capacitor 13 is a sum total of Pi(tₙ), and thus it is given by the following expression.

$${V}_{n} ( {t}_{n} ) = {\sum }_{i = 1}^{N} {P}_{i} ( {t}_{n} ) = T {\sum }_{i = 1}^{N} {w}_{i} {x}_{i} \qquad [ Formula 5 ]$$

Charging by the charging unit 15 (current source 18) is started at the end timing tₙ of the input period T. As described above, in this embodiment, the output period T corresponds to the charging period.

By charging by the charging unit 15, the internal potential of each synapse circuit 8 is increased at the slope α from the end timing tₙ of the input period T. The charging speed α is defined by the high-level value of the charge signal and the resistance value of the resistor 20. It should be noted that the illustration of the change in the internal potential of each synapse circuit 8 in the output period T is omitted from FIG. 6 (the value of the internal potential at the end of the input period T is schematically shown by the broken line).

A pulse signal whose high-level value is equal to that of the input signal may be used as the charge signal. As a matter of course, a pulse signal whose high-level value is different from that of the input signal may be used. Any other electrical signal different from the input signal can be employed as the charge signal.

A multiply-accumulate signal (PWM signal) having a pulse width T, corresponding to the duration from the timing at which the voltage retained by the capacitor 13 exceeds the threshold value θ in the output period T to the end timing tₘ of the output period T is generated.

Assuming that the duty ratio of the pulse width τₙ of the multiply-accumulate signal to the output period T is Rₙ (=ιₙ/T), Rₙ is given by the following expression. It should be noted that the threshold value θ is equal to or larger than the total amount Vₙ(tₙ) of charge.

$${R}_{n} = \frac{T - \frac{( θ - {V}_{n} ( {t}_{n} ) )}{α}}{T} = \frac{1}{α} {\sum }_{i = 1}^{N} {w}_{i} {x}_{i} + \frac{( α T - θ )}{α T} \qquad [ Formula 6 ]$$

Therefore, the multiply-accumulate result obtained by adding up product values (wᵢ*xᵢ) each obtained by multiplying the signal value xᵢ by the weight value wᵢ is given by the following expression.

$${\sum }_{i = 1}^{N} {w}_{i} {x}_{i} = α {R}_{n} - \frac{( α T - θ )}{α T} \qquad [ Formula 7 ]$$

That is, the multiply-accumulate result is a value obtained by subtracting the constant defined by the charging speed α, the threshold value θ, and the output period T from αRₙ=α·(τₙ/T). In this way, the multiply-accumulate signal representing the multiply-accumulate result can be output on the basis of the timing at which the voltage retained by the accumulation unit 11 exceeds the threshold value θ in the output period T having the predetermined duration.

FIG. 7 is a schematic diagram showing a calculation example of a multiply-accumulate signal representing a total multiply-accumulate result based on the multiply-accumulate results of both the positive weight charges and the negative weight charges. In FIG. 7, the multiply-accumulate signal representing the multiply-accumulate result of the positive weight charges is denoted by “Sₙ⁺(t)” and its pulse width is denoted by “τₙ⁺”. Moreover, the multiply-accumulate signal representing the multiply-accumulate result of the negative weight charges is denoted by “Sₙ(t)” and its pulse width is denoted by “τₙ”. Moreover, the multiply-accumulate signal representing the total multiply-accumulate result is denoted by “Sₙ(t)” and its pulse width is denoted by “τₙ”.

The total amount Vₙ⁺(tₙ) of positive weight charge accumulated in the capacitor 13a at the end timing tₙ of the input period T is given by the following expression. It should be noted that wᵢ⁺ represents a positive weight value.

$${V}_{n}^{+} ( {t}_{n} ) = T {\sum }_{i = 1}^{{N}^{+}} {w}_{i}^{+} {x}_{i} \qquad [ Formula 8 ]$$

The total amount Vₙ⁻(tₙ) of the negative weight charge accumulated in the capacitor 13b at the end timing tₙ of the input period T is given by the following expression. It should be noted that wᵢ⁻ represents a negative weight value.

$${V}_{n}^{-} ( {t}_{n} ) = T {\sum }_{i = 1}^{{N}^{-}} \vert {w}_{i}^{-} \vert {x}_{i} \qquad [ Formula 9 ]$$

multiply-accumulate signal Sₙ⁺(t) is Rₙ⁺ (=τₙ⁺/T), the positive multiply-accumulate result obtained by adding up product values (wᵢ⁺*xᵢ) obtained by multiplying the signal value xᵢ by the positive weight value wᵢ⁺ is given by the following expression. It should be noted that it is assumed that the threshold value θ is equal to or larger than the total amount Vₙ⁺(tₙ) of positive weight charge.

$${\sum }_{i = 1}^{{N}^{+}} {w}_{i}^{+} {x}_{i} = α {R}_{n}^{+} - \frac{( α T - θ )}{α T} \qquad [ Formula 10 ]$$

25

In a case where the duty ratio of the negative multiply-accumulate signal Sₙ⁻(t) is Rₙ⁻ (=τₙ⁻/T), a negative multiply-accumulate result obtained by adding up product values (|wᵢ⁻|*xᵢ) obtained by multiplying the input value xᵢ by the negative weight value wᵢ⁻ is given by the following expression. It should be noted that the charge speeda and the threshold value θ are equal to the values used in the expression (Formula 10). Moreover, it is assumed that the threshold value θ is equal to or larger than the total amount Vₙ⁻(tₙ) of negative weight charge.

$${\sum }_{i = 1}^{{N}^{-}} \vert {w}_{i}^{-} \vert {x}_{i} = α {R}_{n}^{-} - \frac{( α T - θ )}{α T} \qquad [ Formula 11 ]$$

Therefore, with the expression (Formula 2) described above, the total multiply-accumulate result is given by the following expression.

$${\sum }_{i = 1}^{N} {w}_{i} {x}_{i} = α ( {R}_{n}^{+} - {R}_{n}^{-} ) ( = α \frac{{τ}_{n}^{+} - {τ}_{n}^{-}}{T} ) \qquad [ Formula 12 ]$$

That is, the total multiply-accumulate result is obtained by the charge speed α, the pulse width τₙ⁺ of the multiply-accumulate signal Sₙ⁺(t), the pulse width τₙ⁻ of the multiply-accumulate signal Sₙ⁻(t), and the output period T. That is, it is possible to easily calculate the multiply-accumulate result on the basis of the timing detected by the comparator 22a and the timing detected by the comparator 22b.

As shown in FIG. 7, it is possible to easily output the multiply-accumulate signal “Sₙ(t)” having the pulse width “τₙ” as the multiply-accumulate signal representing the total multiply-accumulate result. It should be noted that it may be possible to determine which one of the pulse width τₙ⁺ of the multiply-accumulate signal Sₙ⁺(t) and the pulse width τₙ⁻ of the multiply-accumulate signal Sₙ⁻(t) is larger. The multiply-accumulate signal “Sₙ(t)” in a case where the pulse width τₙ⁺ is larger can be output as the positive multiply-accumulate signal and the multiply-accumulate signal “Sₙ(t)” in a case where the pulse width τₙ⁻ is larger can also be output as the negative multiply-accumulate signal. A circuit for comparing the pulse width τₙ⁺ with the pulse width τₙ⁻ can be realized by using an AND circuit, a NOT circuit, and the like as appropriate.

A setting can also be made such that in a case where the ReLU function (ramp function) or the like is used, for example, when the positive multiply-accumulate signal “Sₙ(t)” is obtained, the signal is output as it is, and when the negative multiply-accumulate signal “Sₙ(t)” is obtained, 0 is output.

As the setting of the charging speeda and the threshold value θ, α=θ/ T is set for the output period T. Accordingly, the constant determined by the charge speed α, the threshold value θ, and the output period T included in the expressions (Formula 6), (Formula 7), (Formula 10), and (Formula 11) can be set to be zero, and the processing can be simplified.

For example, the high-level value of the charge signal and the resistance value of the resistor 20 are set as appropriate to adjust the charging speed α. The threshold value θ is set on the basis of the duration of the input period T. Accordingly, it is possible to exert advantageous effects.

[Analog Circuit According to TACT Method]

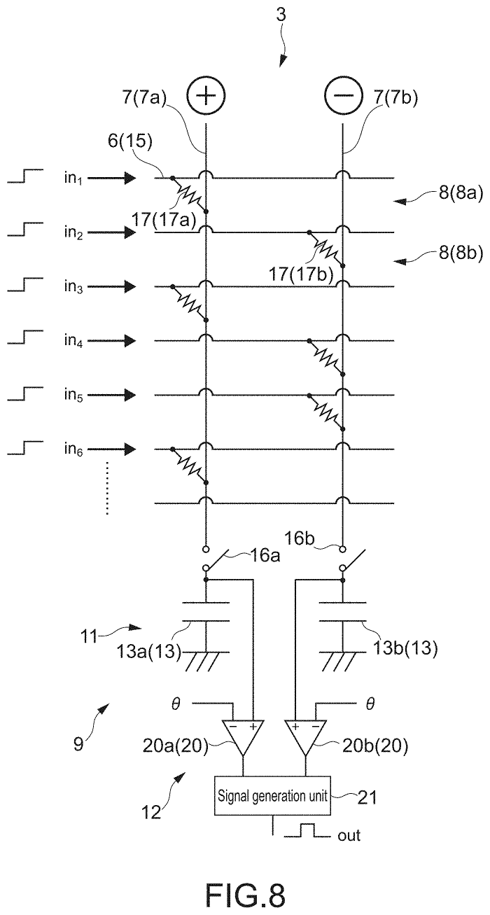

FIG. 8 is a schematic circuit diagram showing an example of the analog circuit 3 according to the TACT method. Pulse signals (TACT signals) are input into the plurality of input signal lines 6 as input signals in₁ to in 6 at a timing corresponding to the signal value xᵢ.

Here, a continuous pulse signal that rises to a timing corresponding to the input value and keeps the ON level as illustrated in FIG. 2B is input. Regarding the pulse signal, the duration of the ON time with respect to the input period T corresponds to the input value in the input period T. Hereinafter, the duration of the ON time in the input period T will be referred to as a pulse width in the input period T in some cases.

At a timing at which the input period T elapses, the charges accumulated in the capacitor 13a are the sum total σ⁺ of the positive weight charges each corresponding to the product value of the positive weight value wᵢ⁺. Also, the charges accumulated in the capacitor 13b are the sum total o of the negative weight charges each corresponding to the product value of the negative weight value wᵢ⁻.

Since the ON level of the electrical signal is maintained also after the input period T ends, charges are accumulated in the capacitor 13a and the capacitor 13b. A multiply-accumulate signal (PWM signal) representing the multiply-accumulate result of the positive weight charges is generated on the basis of the timing at which the voltage retained by the capacitor 13a exceeds the threshold value θ.

Moreover, a multiply-accumulate signal (PWM signal) representing the multiply-accumulate result of the negative weight charges is generated on the basis of the timing at which the voltage retained by the capacitor 13b exceeds the threshold value θ. A multiply-accumulate signal representing the total multiply-accumulate result can be generated on the basis of these positive and negative multiply-accumulate signals.

In the analog circuit 3 according to the TACT method shown in FIG. 8, the output period T corresponds to the charging period. Moreover, the input signals ini to in 6 input into the plurality of input signal lines 6 in the output period T corresponds to the charge signal.

Therefore, the analog circuit 3 according to the TACT method illustrated in FIG. 8, the same charge signal is supplied to the capacitors 13a and 13b via the plurality of input signal lines 6. Although not shown in the figure, a configuration for inputting the input signals in₁ to in₆ into the plurality of input signal lines 6 during the output period T corresponds to the charging unit 15. Accordingly, the configuration for inputting the input signals in₁ to in₆ also functions as the charging unit 15. As shown in FIG. 8, it is also possible to consider the plurality of input signal lines 6 itself as a part of the charging unit 15.

Here, the inventor has considered the time constant as a parameter associated with the accumulation of charges of the capacitor 13 in the input period T and the output period (charging period) T. Hereinabove, the accumulation of charges in the input period T and the output period T is approximated as a linear change and described using the “slope wᵢ” and the “slope α” as shown in FIG. 6. As a matter of course, the analog-type arithmetic apparatus 100 capable of accurately performing predetermined arithmetic processing including the multiply-accumulate operation can be realized on the basis of such an approximation.

On the other hand, it is considered that the charges (potential) of the capacitor 13 are accumulated in accordance with the time constant determined by the circuit configuration of the analog circuit 3 shown in FIGS. 5 and 8 in the input period T and the output period (charging period) T. Therefore, the inventor thought that a more accurate multiply-accumulate operation could be achieved on the basis of the accumulation of charges according to the time constant by designing the circuit configuration as appropriate.

Hereinafter, the charges (potential) of the capacitor 13 will be sometimes described as the (charges) potential of the output line 7 for outputting charges to the capacitor 13.

The inventor found a configuration that makes the time constant for the output lines 7 irrespective of the number of resistors 17 disposed between the output lines 7 and the plurality of input signal lines 6.

First, it is assumed that the capacitors 13 a and 13b functionally include a parasitic capacitance (not shown) generated in the output lines 7a and 7b. In this case, a minimum value of the capacitance that can be taken by the capacitors 13a and 13b is a parasitic capacitance generated in the output lines 7. For example, even in a case where the capacitors 13 are not provided, charges are accumulated on the basis of the parasitic capacitance generated in the output lines 7a and 7b and a multiply-accumulate signal can be generated on the basis of the threshold determination. The same applies to the analog circuit 3 according to the PWM method illustrated in FIG. 5.

The time constant of the output lines 7 sequentially changes in accordance with the number of input signals sequentially input over time and the number of resistors 17 (on-resistances) in a state capable of transmitting a signal to the output lines 7. Here, the focus is placed on the time constant at the end of the input period T. In the analog circuit 3 according to the TACT method according to this embodiment, signals are input into all of the input signal lines 6 at the end of the input period T. Therefore, the number of input signals at the end of the input period T takes a maximum value and a constant value. As a result, the time constant at the end of the input period T sequentially changes in accordance with the number of on-resistances.

Here, the resistance values of the resistors 17 are set to be the same resistance value R. In other words, a binary connect configuration is employed. Moreover, the parasitic capacitance of each synapse circuit 8 is designed to be a constant capacitance C. Since the resistors 17 are connected in parallel to one output line 7, the combined resistance is R/N in a case where N resistors 17 are connected (the number of on-resistances is N). On the other hand, since the number of synapse circuits 8 is N which is equal to the number of resistors 17, the combined capacitance is NC.

For example, a multiply-accumulate signal is generated on the basis of the parasitic capacitance of each synapse circuit 8 without providing the capacitors 13. In this case, the value of the combined resistance x combined capacitance is RC irrespective of the number of resistors 17 (number of on-resistances). Therefore, the time constant of the output lines 7 at the end of the input period T is also RC irrespective of the number of resistors 17.

In a case where the capacitors 13 are installed, the capacitance of the capacitors 13 is set to a value (number of resistors 17×C₀) obtained by multiplying a predetermined constant Co by the number of resistors 17 (number of on-resistances). Accordingly, the time constant is R/N×(NC+NC₀)=R×(C+C₀) and is constant irrespective of the number of resistors 17. Thus, the time constant can be made constant irrespective of the number of resistors 17.

Therefore, the potential V of each output line 7 at the end of the input period T can be approximated by the following expression.

$$V = {V}_{c} ( 1 - {e}^{- \frac{{t}_{ave}}{R \cdot C}} ) \qquad [ Formula 13 ]$$

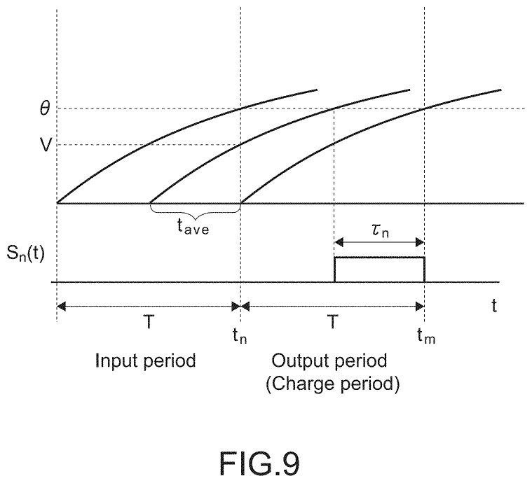

FIG. 9 is a schematic graph for describing the potential V of each output line 7 at the end of the input period T. The potential V of each output line 7 at the end of the input period T will be described with reference to the expression (Formula 13) and FIG. 9. It should be noted that the time constant curve in the graph of FIG. 9 is a curve corresponding to the expression (Formula 13).

“Vc” represents a constant and is a value corresponding to the convergence value of the potential after a time equal to or longer than the time constant has elapsed.

“tₐᵥₑ” represents the average of pulse widths of the pulse signals input into the input signal lines 6 within the input period T.

It should be noted that the change in the charge of each output line 7 until the end of the input period T does not always occur in accordance with the time constant curve shown in FIG. 9. It was found that at least the potential V of each output line 7 at the end of the input period T can be approximated by the expression (Formula 13).

On the other hand, in the output period (charging period) T, the input signals ini to in 6 (charge signals) at the ON level are input into all the input signal lines 6. Therefore, it can be considered that the change in charge in the output period (charging period) T is performed in accordance with the time constant curve shown in FIG. 9.

Here, it is assumed that the potential V of each output line 7 at the end timing tₙ of the input period T, which is approximated by the expression (Formula 13), is denoted by “Vtₙ”. Moreover, the time from the end timing tₙ of the input period T (time within the output period T) is set to t. Then, the potential “Vₒᵤₜ” of each output line 7 in the output period T can be approximated by the following equation.

$${V}_{out} = {V}_{{t}_{n}} + ( {V}_{in} - {V}_{{t}_{n}} ) ( 1 - {e}^{- \frac{t}{R \cdot C}} ) \qquad [ Formula 14 ]$$

Here, as shown in FIG. 9, the input period T and the threshold value θ are determined in accordance with the time constant curve corresponding to the expression (Formula 13). That is, the potential V when the input period T is substituted for “tₐᵥₑ” of (Formula 13) is set as the threshold value θ. Accordingly, in a case where the maximum pulses whose pulse width in the input period T is maximum are input into all the input signal lines 6, the potential of the output line 7 exceeds the threshold value at the end timing of the input period T (start timing of the output period T).

On the other hand, in a case where the pulses whose pulse width in the input period T is 0 are input into all the input signal lines 6, the potential of the output line 7 exceeds the threshold value at the end timing of the output period T. As a result, it is possible to accurately calculate the multiply-accumulate signal with high resolution within the output period T. That is, by setting the threshold value θ on the basis of the duration of the input period T, an advantageous effect can be exhibited.

As shown in FIG. 9, the threshold determination is performed on each of the capacitors 13a and 13b on the basis of the threshold value θ. Accordingly, the multiply-accumulate signal “Sₙ(t)” using “tₐᵥₑ” that is the average of the pulse widths of the respective pulse signals in the input period T as the pulse width “τₙ” can be generated and output accurately. Thus, it was found that the pulse width “τₙ” of the multiply-accumulate signal “Sₙ(t)” can also be approximated by the expression (Formula 13).

Irrespective of how the number of resistors 17 for connecting the input signal lines 6 and the positive charge output line 7a (i.e., the number of positive weight multiplication units), and the number of resistors 17 for connecting the input signal lines 6 and the negative charge output line 7b (i.e., the number of negative multiplication units) are combined in each analog circuit 3, the multiply-accumulate operation illustrated in FIG. 9 is realized for the potential V⁺ of the positive charge output line 7a and the potential V⁻ of the negative charge output line 7b.

Therefore, as illustrated in FIG. 7, the multiply-accumulate signal “Sₙ(t)” representing the total multiply-accumulate result can be calculated on the basis of the pulse width τₙ⁺ of the multiply-accumulate signal Sₙ⁺(t) and the pulse width τₙ⁻ of the multiply-accumulate signal Sₙ⁻(t).

It should be noted that even in a case where other configurations are employed, the analog circuit 3 is designed such that the time constant of the positive charge output line 7a is equal to the time constant of the negative charge output line 7. Thus, the multiply-accumulate operation illustrated in FIG. 9 is realized with respect to the potential V⁺ of the positive charge output line 7a and the potential V⁻ of the negative charge output line 7b.

As a matter of course, the present technology is not limited to the case where the binary connect configuration is employed in which the positive weight value wi⁺ and the absolute value of the negative weight value wi⁻ are fixed to the same value.

For example, the positive weight value wi⁺ and the absolute value of the negative weight value wi⁻ are multivalued. That is, the positive weight value wi⁺ and the absolute value of the negative weight value wi⁻ are set to any of the plurality of values different from each other. Alternatively, the positive weight value wi⁺ and the absolute value of the negative weight value wi⁻ are randomly set.

Also in such a case, the analog circuit 3 is designed such that the time constant of the positive charge output line 7a is equal to the time constant of the negative charge output line 7. Thus, the multiply-accumulate operation described shown in FIG. 9 is realized with respect to the potential V⁺ of the positive charge output line 7a and the potential V⁻ of the negative charge output line 7b.

In the present disclosure, the time constant of the output line 7 is included in a time constant associated with the output of the charge corresponding to the product value to the output line 7 by the plurality of synapse circuits 8. The time constant of the positive charge output line 7a is included in the time constant associated with the output of the positive charge to the positive charge output line 7a by the plurality of positive weight multiplication units 8a. The time constant of the negative charge output line 7b is included in the time constant associated with the output of the weight charge to the negative charge output line 7b by the plurality of weight multiplication units 8b.

Next, consider in the analog circuit 3 according to the PWM method illustrated in FIG. 5. In the analog circuit 3 according to the PWM method illustrated shown in FIG. 5, the input signals ini to in 6 are input into the plurality of input signal lines 6 in the input period T. Then, the charge signal CH is input via the charging line 19 in the output period T.

Here, the potential V of the output line 7 at the end of the input period T can be approximated by the expression (Formula 13) as in the TACT method. That is, as shown in FIG. 9, it can be approximated by the time constant curve according to the time constant of the output line 7. Thereafter, the charging line 19 and the resistance value of the resistor 20 are designed such that the charging by the charging unit 15 is performed in accordance with the same time constant curve. Accordingly, the multiply-accumulate operation illustrated in FIG. 9 is realized.

For example, in the configuration shown in FIG. 5, the combined resistance of the positive resistor 17a and the resistance value of the resistor 20a connected to the charging line 19 are made to equal. Accordingly, the multiply-accumulate operation illustrated in FIG. 9 is realized with respect to the positive charge output line 7a. Moreover, the combined resistance of the negative resistor 17b and the resistance value of the resistor 20b connected to the charging line 19 are made to equal. Accordingly, the multiply-accumulate operation illustrated in FIG. 9 is realized with respect to the negative charge output line 7b.

For example, the analog circuit 3 is designed such that the time constant of the positive charge output line 7a and the time constant of the negative charge output line 7b in the input period T are equal. Then, the combined resistance of the positive resistor 17a and the resistance value of the resistor 20 a are made to equal and the combined resistance of the negative resistor 17b and the resistance value of the resistor 20b are made to equal.

Thus, the multiply-accumulate operation illustrated in FIG. 9 is realized in accordance with the same time constant with respect to the potential V⁺ of the positive charge output line 7 a and the potential V⁻ of the negative charge output line 7b. As a result, the multiply-accumulate signal “Sₙ(t)” having, as the pulse width “τₙ”, the average of the pulse widths of the respective pulse signals in the input period T can be accurately generated and output.

As a matter of course, the application of the present technology is not limited to the case where the multiply-accumulate operation illustrated in FIG. 9 is realized. Other configurations and other multiply-accumulate operation may be performed as the analog circuit 3 according to the PWM method and the analog circuit 3 according to the TACT method. In any case, the result of the multiply-accumulate operation can be obtained on the basis of the potential of the positive charge output line 7a (the voltage retained in the capacitor 13a) V⁺ and the potential of the negative charge output line 7b (the voltage retained in the capacitor 13b) V⁻.

In this embodiment, the analog circuit 3 according to the PWM method and the analog circuit 3 according to the TACT method both include the plurality of input signal lines 6, the plurality of synapse circuits 8, the accumulation unit 11, the charging unit 15, and the signal output unit 12.

The accumulation unit 11 includes the capacitor 13a capable of accumulating the positive weight charge generated by the synapse circuit (positive weight multiplication unit) 8a and the capacitor 13b capable of accumulating the negative weight charge generated by the synapse circuit (negative weight multiplication unit) 8b.

The charging unit 15 charges the capacitors 13a and 13b after the input period T. The signal output unit 12 can output the multiply-accumulate signal by performing threshold determination using the predetermined threshold value on each of the capacitors 13a and 13b. It should be noted that the predetermined threshold value may be set on the basis of the duration of the input period.

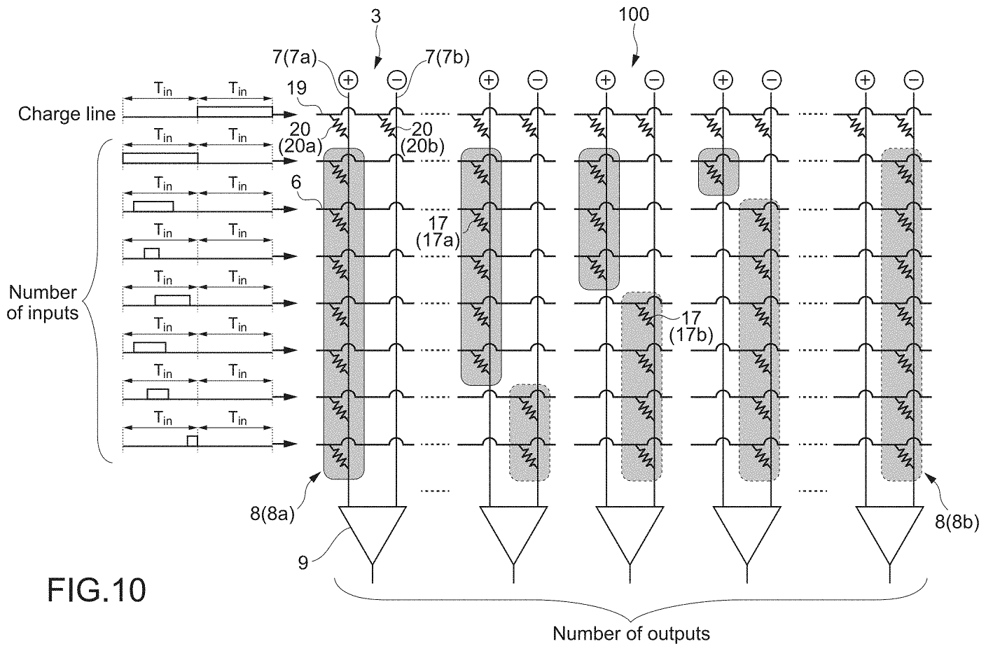

FIGS. 10 to 13 are schematic diagrams each showing an example of the configuration of the arithmetic apparatus 100.

The arithmetic apparatus 100 illustrated in FIGS. 10 to 13 includes the plurality of input signal lines 6 and the plurality of analog circuits 3 connected in parallel to the plurality of input signal lines 6. By employing such a configuration, it is possible to input an electrical signal in parallel into each analog circuit 3 and it is possible to increase the arithmetic processing speed. As a result, it is possible to exhibit excellent operation performance.

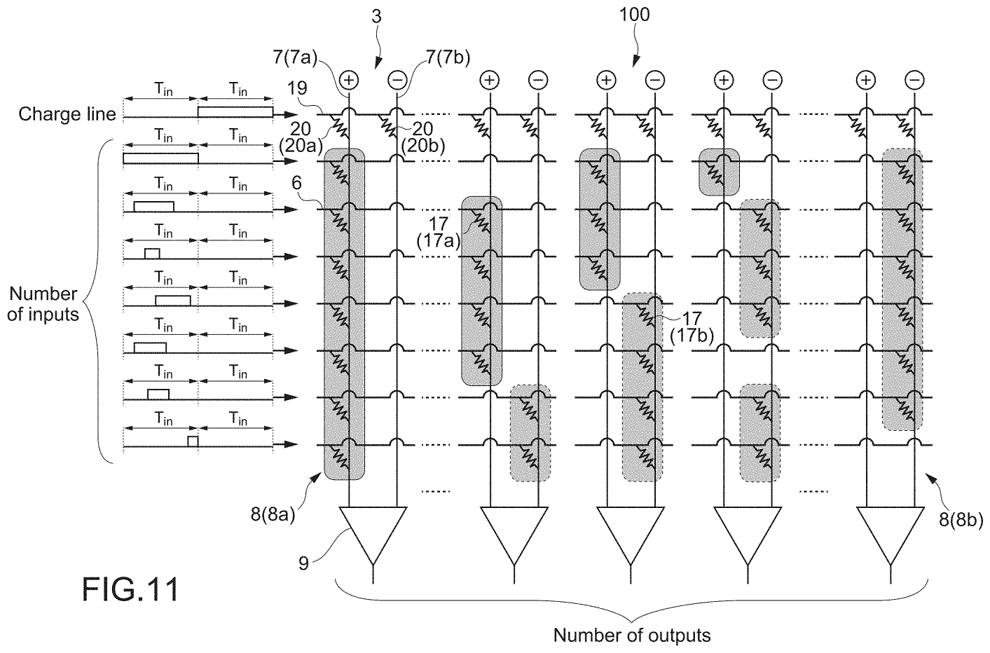

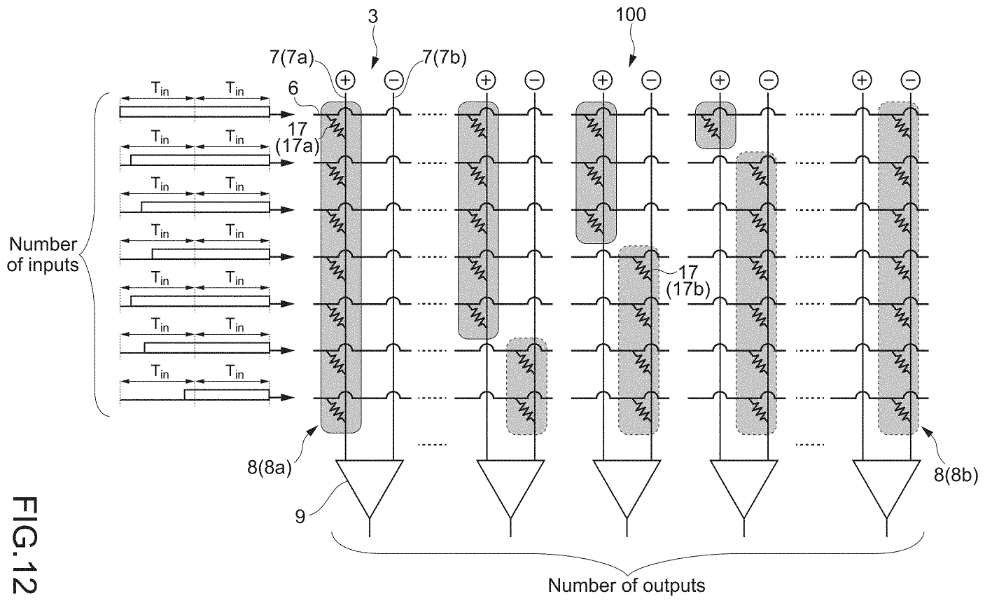

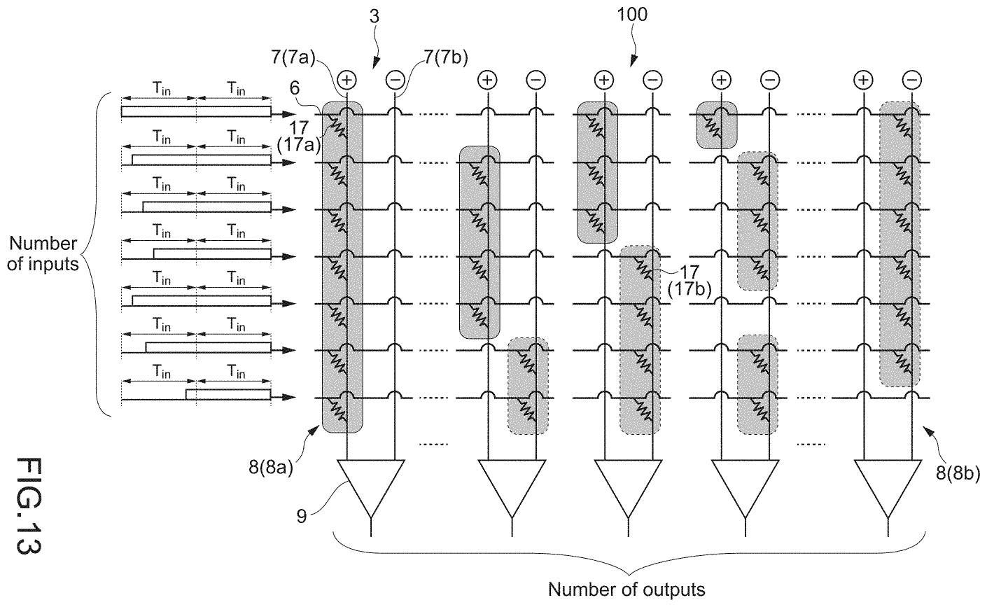

In the arithmetic apparatus 100 illustrated in FIGS. 10 and 11, the analog circuits 3 according to the PWM method described with reference to FIGS. 5 to 7 are arranged as a plurality of analog circuits 3. In the arithmetic apparatus 100 illustrated in FIGS. 12 and 13, the analog circuits 3 according to the TACT method described with reference to FIGS. 8 and 9 are arranged as the plurality of analog circuits 3.

In this embodiment, charging by the charging unit 15 is performed on the plurality of analog circuits 3 on a common charging mode. Moreover, a common threshold value is set as the predetermined threshold value used for the threshold determination by the signal output unit 12 in the neuron circuit 9. That is, the charging is performed on the same charging mode in each analog circuit 3 and the threshold determination is performed using the same threshold value.

In the analog circuit 3, the common charging mode is performed on each of the capacitors 13a and 13b. That is, the charging is performed on the plurality of capacitors 13a and 13b included in the plurality of analog circuits 3 on the common charging mode. Then, the threshold determination is performed at the plurality of analog circuits 3 by using the common threshold value, and the multiply-accumulate signal is output.

The common charging mode can be charging for supplying the charge signal in each analog circuits 3 in a common charging period. Moreover, the common charging mode also includes a mode on which the same charge signal is supplied in each analog circuit 3. Also, the common charging mode includes charging at a common charging speed (charging rate), charging according to a common time constant, and the like. As a matter of course, the present technology is not limited thereto.

For example, as shown in FIGS. 10 and 11, a common charging line 19 is arranged for the plurality of analog circuits 3. The charging line 19 is arranged to be parallel to the plurality of input signal lines 6. The resistor 20a is connected between the charging line 19 and the positive charge output line 7a of each analog circuit 3. The resistor 20b is connected between the charging line 19 and the negative charge output line 7b of each analog circuit 3.

The charge signal that becomes ON level during the output period (charging period) T is input via the charging line 19. Thus, it is possible to supply the same charge signal in the common charging period. Resistors all having the same resistance value are arranged as the resistors 20a and 20b. Thus, it is possible to perform charging at the common charging rate in the common charging speed.

For example, it is assumed that charging at the common charging speed is performed in the common charging period. In this case, the potential of the positive charge output line 7a and the potential of the negative charge output line 7b of each analog circuit 3 rise in accordance with the charging speed a as illustrated in FIG. 6.

Thus, as illustrated in FIG. 7, the multiply-accumulate signal “Sₙ(t)” representing the total multiply-accumulate result can be calculated on the basis of the pulse width Tₙ⁺ of the multiply-accumulate signal Sₙ⁺(t) and the pulse width τₙ⁻ of the multiply-accumulate signal Sₙ⁻(t) in each analog circuit 3.

Moreover, each analog circuit 3 and the charging unit 15 are designed such that the time constant of each output line 7 (the positive charge output line 7a or the negative charge output line 7b) in the output period T is a common value. In this case, it is possible to realize charging according to the common time constant.

Each analog circuit 3 is designed such that the time constant of the positive charge output line 7a and the time constant of the negative charge output line 7b in the input period T in each of the plurality of analog circuits 3 are equal and that the value of the time constant is a common value in all the analog circuits 3. Then, the charging unit 15 is designed such that the time constant of the positive charge output line 7a and the time constant of the negative charge output line 7b in the output period T are equal to the time constant in the input period T. Accordingly, the multiply-accumulate operation illustrated in FIG. 9 is realized in each analog circuit 3. It should be noted that the threshold value is determined on the basis of the input period T in accordance with the time constant curve and is set as a common threshold value.

Moreover, as shown in FIGS. 12 and 13, an input signal is input such that the ON state is maintained in the output period T. Accordingly, charging in which the same charge signal is supplied during the common charging period is performed.

Moreover, each analog circuit 3 and the charging unit are designed such that the time constant of each output line 7 (positive charge output line 7a, negative charge output line 7b) is a common value. In this case, it is possible to realize charging according to the common time constant. Accordingly, the multiply-accumulate operation illustrated in FIG. 9 can be realized in each analog circuit 3. It should be noted that the threshold value is determined on the basis of the input period T in accordance with the time constant curve and is used as a common threshold value.

Here, the inventor has further considered the output of the multiply-accumulate signal by the analog circuit 3 when the charging according to the common charging mode is performed and when the threshold determination using the common threshold value is performed. Then, the inventor found that the accuracy of the multiply-accumulate operation is improved by outputting the multiply-accumulate signal as appropriate from each analog circuit 3 in a common output period T. In other words, the inventor found that the accuracy of the multiply-accumulate operation is improved by increasing the number of analog circuits capable of outputting the multiply-accumulate signal in the common output period T.

For example, it is assumed that the binary connect configuration is employed in the arithmetic apparatus 100 illustrated in FIGS. 10 and 11. In binary connects, the positive weight value and the absolute value of the negative weight are fixed to the same value. That is, the resistance values of the resistors 17 are all fixed to the same value.

In the configuration shown in FIG. 10, the sum of the number of positive resistors 17a and the number of negative resistors 17b is set to a common value (seven) at each analog circuit 3. Therefore, with the configuration shown in FIG. 10, in the plurality of analog circuits 3, a value obtained by adding a sum total of the positive weight values (hereinafter, referred to as positive sum total value) set at the plurality of synapse circuits 8 and a sum total of the absolute values of the negative weight values (hereinafter, referred to as negative sum total value) set at the plurality of synapse circuits 8 is a common value.

It should be noted that the value obtained by adding the positive sum total value and the negative sum total value corresponds to a sum total of the absolute values of the weight values set in the plurality of synapse circuits 8, and will be hereinafter referred to as a weight sum total value.

In the configuration shown in FIG. 11, the sum of the number of positive resistors 17a and the number of negative resistors 17b is not set to a common value at each analog circuit 3. For example, the total number of resistors 17 may be set to any of a plurality of numbers different from each other. Alternatively, the total number of resistors 17 may be randomly set.

Therefore, with the configuration shown in FIG. 11, in the plurality of analog circuits 3, the value (weight sum total value) obtained by adding the positive sum total value and the negative sum total value is not a common value. For example, it is possible to realize a configuration in which the sum total weight value is any of a plurality of values different from each other. Alternatively, it is also possible to realize a configuration in which the sum total weight value is a random value.

It should be noted that in the configuration shown in FIG. 11, there is synapse circuits 8 in which both the positive resistor 17a and the negative resistor 17b are not set. It can be said that such a synapse circuit 8 is a multiplication unit corresponding to a term where the weight value is zero in the multiply-accumulate operation.

Regarding the configurations shown in FIGS. 10 and 11, it is assumed that configurations other than the binary connect are employed. The positive weight value and the absolute value of the negative weight value are multivalued. Alternatively, the positive weight value and the absolute value of the negative weight value are randomly set.

As for the value (weight sum total value) obtained by adding the positive sum total value and the negative sum total value, any of a configuration in which such a value is a common value, a configuration in which such a value is any of a plurality of values different from each other, and a configuration in which such a value is a random value can be realized.

For example, the arithmetic apparatus 100 illustrated in FIGS. 10 and 11 can be realized using as appropriate the resistors 17 having multivalued resistance values or the resistors 17 having random resistance values on the condition that the weight sum total value is a common value or the weight sum total value is any of the plurality of values different from each other.

The same applies to the arithmetic apparatus 100 illustrated in FIGS. 12 and 13. For example, in a case where the binary connect configuration is employed, with the configuration shown in FIG. 12, the weight sum total value is a common value in the plurality of analog circuits 3. With the configuration shown in FIG. 13, the weight sum total value is not a common value in the plurality of analog circuits 3. For example, it is possible to realize a configuration in which the sum total weight value is any of the plurality of values different from each other. Alternatively, it is also possible to realize a configuration in which the sum total weight value is a random value.

Regarding the configurations shown in FIGS. 12 and 13, it is assumed that configurations other than the binary connect are employed. In this case, any of a configuration in which the weight sum total value is a common value, a configuration in which the weight sum total value is any of the plurality of values different from each other, and a configuration in which the weight sum total value is a random value can be realized.

The charging according to the common charging mode and the threshold determination using the common threshold value are performed on the multi-input x multi-output arithmetic apparatus 100 having such various configurations, to thereby cause each analog circuit 3 to properly output the multiply-accumulate signal. For that, the inventor has focused on the weight sum total value, the positive sum total value, and the negative sum total value in each analog circuit 3.

Then, the inventor newly devised to perform charging on the basis of a maximum value of the weight sum total value among the plurality of analog circuits 3 and to perform threshold determination using a threshold value based on the maximum value of the weight sum total value among the plurality of analog circuits 3. That is, the inventor newly devised a technology of performing charging on the basis of the maximum value among the weight sum total values in the plurality of analog circuits 3 and performing threshold determination using a threshold value based on the maximum value.

For example, in the configurations shown in FIGS. 10 and 11, the combined resistance in a case of connecting all the resistors 17 included in the analog circuit 3 whose weight sum total value is the maximum in parallel is used as a common resistance value. Then, the resistance values of all the resistors 20a and 20b are unified into that common resistance value. In this case, charging according to the common time constant is realized in the output period T.

This charging corresponds to charging in which the time constant associated with the output of the charges corresponding to the product values to the output line 7 by the plurality of synapse circuits 8 whose weight sum total value is the maximum value is used as the common time constant.

[0 0 6 4] The threshold value is determined on the basis of the input period T in accordance with the time constant curve commonly defined by the resistance value. Thus, it is possible to cause each analog circuit 3 to output the multiply-accumulate signal in the common output period T. Accordingly, it is possible to improve the accuracy of the multiply-accumulate operation. It should be noted that the threshold value corresponds to the threshold value based on the maximum value.

Moreover, the inventor newly devised to perform charging based on the maximum value among the positive sum total values and the negative sum total values in the plurality of analog circuits 3 and to perform threshold determination using a threshold value based on the maximum value among the positive sum total values and the negative sum total values in the plurality of analog circuits 3. That is, the inventor devised to compare the positive sum total value and the negative sum total value of each analog circuit 3 over all the plurality of analog circuits 3, perform charging on the basis of the maximum value among them, and perform threshold determination using the threshold value based on the maximum value.

Here, the maximum value among the positive sum total values and the negative sum total values in the plurality of analog circuits 3 is defined as a maximum sum total value.

The positive weight charge or the negative weight charge related to the maximum sum total value is defined as a maximum weight charge. For example, it is assumed that the positive sum total value of one of the analog circuits 3 of the plurality of analog circuits 3 is the maximum sum total value. In the input period T, the positive weight charge output from the positive charge output line 7a in that analog ciruit 3 is the maximum weight charge.

Alternatively, it is assumed that the negative sum total value of one analog circuit 3 is the maximum sum total value. In the input period T, the negative weight charge output from the negative charge output line 7b in that analog circuit 3 is the maximum weight charge.

It should be noted that the maximum weight charge is a parameter unrelated to the level or the like of the input signal. That is, regardless of what signal is input as the input signal, the positive weight charge or the negative weight charge output from the positive weight output line or the negative weight output line, which is the maximum sum total value, is the maximum weight charge.

The positive charge output line or the negative charge output line from which the maximum weight charge is output is defined as a maximum charge output line.

In the configurations shown in FIGS. 12 and 13, the combined resistance of the resistors 17 connected to the maximum charge output line is used as a common resistance value. Then, the resistance values of all the resistors 20a and 20b are unified into that common resistance value. In this case, charging according to the common time constant is realized in the output period T. It should be noted that the combined resistance of the resistors 17 connected to the maximum charge output line is a parameter corresponding to the maximum sum total value.

This charging corresponds to charging in which the time constant associated with the output of the maximum weight charge to the maximum charge output line is used as the common time constant.

The threshold value is determined on the basis of the input period T in accordance with the time constant curve commonly defined by the resistance value. Thus, it is possible to cause each analog circuit 3 to output the multiply-accumulate signal in the common output period T. Accordingly, it is possible to improve the accuracy of the multiply-accumulate operation. It should be noted that the threshold value corresponds to a threshold value based on the maximum sum total value.

It should be noted that it is assumed that the weight sum total value of the analog circuit 3 in which all resistors 17 are connected to only one of the positive charge output line or the negative charge output line is a maximum value in the plurality of analog circuits 3. In this case, the maximum value of the weight sum total value is also the maximum sum total value that is the maximum value among the positive sum total values and the negative sum total values. Therefore, the charging is performed on the same charging mode and the threshold determination is performed by using the same threshold value.

In the configurations shown in FIGS. 12 and 13, the threshold value is set in accordance with the time constant curve in a case of inputting the charge signal in the output period T into the output line to which all the resistors 17 included in the analog circuit 3 whose weight sum total value is the maximum value are connected in parallel. It should be noted that the output line to which all of the resistors 17 included in the analog circuit 3 whose weight sum total value is the maximum value are connected in parallel is not always present in practice.

By setting such a threshold value, the multiply-accumulate signal can be output in each analog circuit 3 during the common output period T. Accordingly, it is possible to improve the accuracy of the multiply-accumulate operation. It should be noted that the threshold value corresponds to the threshold value based on the maximum value.

Moreover, the threshold value is set to the maximum charge output line in accordance with the time constant curve in a case of inputting the charge signal in the output period T. Thus, the multiply-accumulate signal can be output in each analog circuit 3 during the common output period T. As a result, it is possible to improve the accuracy of the multiply-accumulate operation. It should be noted that the threshold value corresponds to the threshold value based on the maximum sum total value.

It should be noted that it is assumed that the weight sum total value of the analog circuit 3 in which all resistors 17 are connected to only one of the positive charge output line or the negative charge output line is a maximum value in the plurality of analog circuits 3. In this case, the maximum value of the weight sum total value is also the maximum sum total value that is the maximum value among the positive sum total values and the negative sum total values. Therefore, the threshold determination is performed at the same threshold value.

As a matter of course, the present technology is not limited to such charging mode and setting of the threshold value. Any configuration and method for realizing the charging according to the common charging mode and the threshold determination using the common threshold value may be employed. Moreover, those may be combined with the configuration and the method or the like for realizing the multiply-accumulate operation illustrated in FIG. 9 described above.

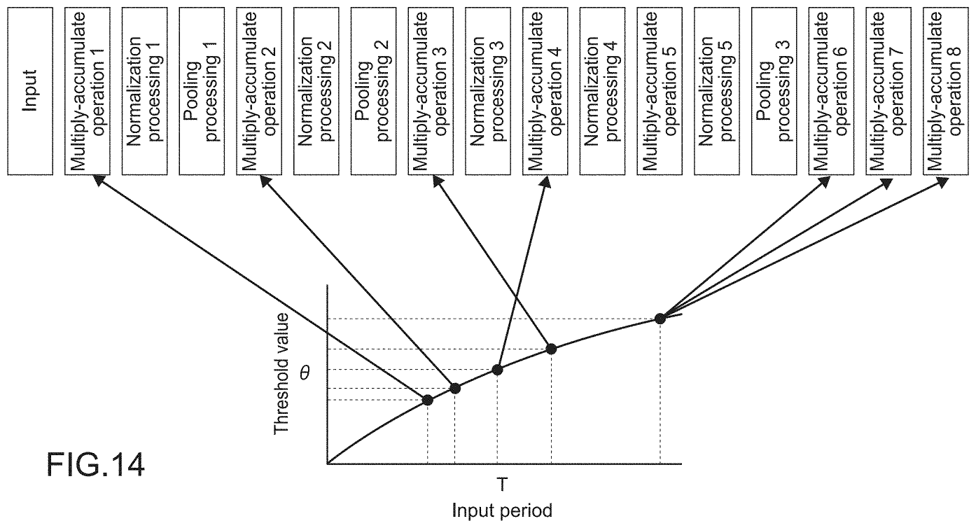

FIG. 14 is a schematic diagram showing a configuration example of the neural network. For example, as shown in FIG. 14, a neural network is realized by performing a plurality of multiply-accumulate operations, a plurality of normalization processes, and a plurality of pooling processes.

Here, the multiply-accumulate operation corresponds to the output of a plurality of multiply-accumulate results by the arithmetic apparatus 100 including the plurality of analog circuits 3. The normalization processing is processing of normalizing the input signal for the input of the multiply-accumulate operation at the next stage. The pooling processing is processing of reducing the number of input signals in accordance with the number of inputs of the multiply-accumulate operation at the next stage. By the normalization processing and the pooling processing, it is possible to simplify the processing and shorten the processing time.

It should be noted that in FIG. 14, a case where the arithmetic apparatus 100 that performs each of multiply-accumulate operations 1 to 8 is constituted by the plurality of analog circuits 3 designed with a common time constant is shown. That is, the charging according to the common time constant is performed on the common charging mode in each arithmetic apparatus 100.

In each arithmetic apparatus 100, the common input period T and the common threshold value θ are set on the basis of the common time constant curve. On the other hand, in the example shown in FIG. 14, different input periods T and different threshold values are set to different arithmetic apparatuses 100. The present technology is not limited thereto, and the common input period T and the common threshold value θ may be set to all the arithmetic apparatuses 100.

As a matter of course, the arithmetic apparatus 100 is constituted by the analog circuits 3 each having another configuration and the multiply-accumulate operations may be performed. Also in this case, it is possible to realize efficient and high-speed arithmetic processing by setting the common charging mode and the common threshold value in each analog circuit 3.

As described above, in the arithmetic apparatus 100 according to this embodiment, the common charging mode is performed and the common threshold value is set with respect to the one or more analog circuits 3. Accordingly, it is possible to realize efficient and high-speed arithmetic processing in the analog circuit that performs the multiply-accumulate operation. That is, by arranging a plurality of sets of the plurality of analog circuits 3 in parallel, simultaneous parallel operations can be performed at a time by one-time input, and high-speed operation and efficient operation are realized.

### Other Embodiments

The present technology is not limited to the embodiment described above, and various other embodiments can be realized.

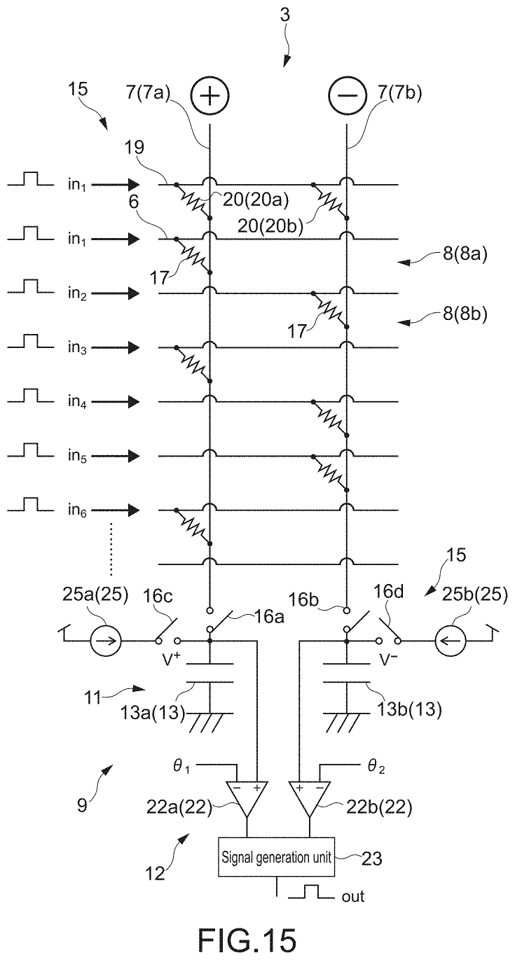

FIG. 15 is a schematic circuit diagram showing another example of the analog circuit 3 according to the PWM method. In the analog circuit 3 illustrated in FIG. 15, two current sources 25a and 25b are provided as the charging unit 15.

The current source 25a is connected to the side (side opposite to the GND) of the capacitor 13a, which is connected to the positive charge output line 7a, via a switch 16c. The current source 25b is connected to the side (side opposite to the GND) of the capacitor 13b, which is connected to the negative charge output line 7b, via a switch 16d.

In the analog circuit 3 illustrated in FIG. 15, the capacitors 13a and 13b are charged at the same charging speed by the current sources 25a and 25b. Accordingly, the potential V⁺ of the positive charge output line 7a (the voltage retained by the capacitor 13a) and the potential V⁻ of the negative charge output line 7b (the voltage retained by the capacitor 13b) are each increased. The specific configuration of the current source 25 is not limited, and may be arbitrarily designed.

Even in a case where such a configuration is employed, the charging according to the common charging mode and the threshold determination using the common threshold value can be performed on one or more analog circuits 3. For example, in a case of arranging the plurality of analog circuits 3 in parallel, the charging according to the common charging mode and the threshold determination using the common threshold value is performed. Accordingly, it is possible to realize efficient and high-speed arithmetic processing.

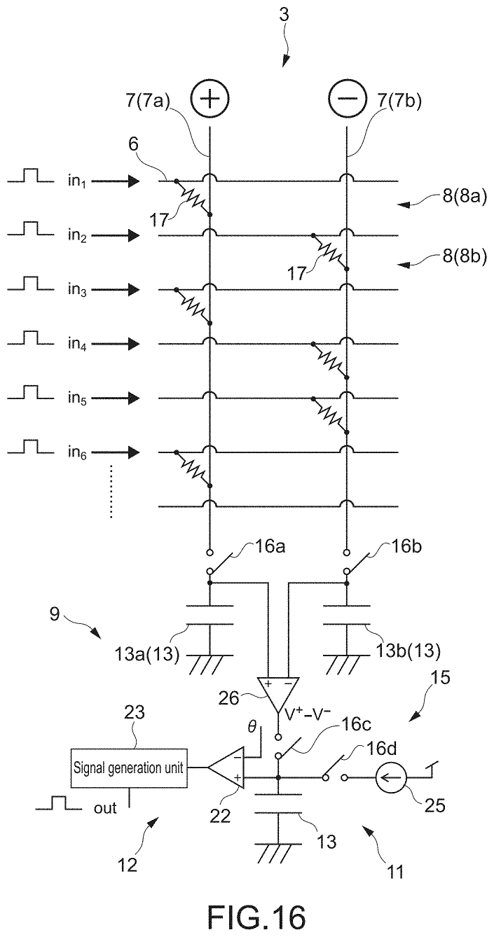

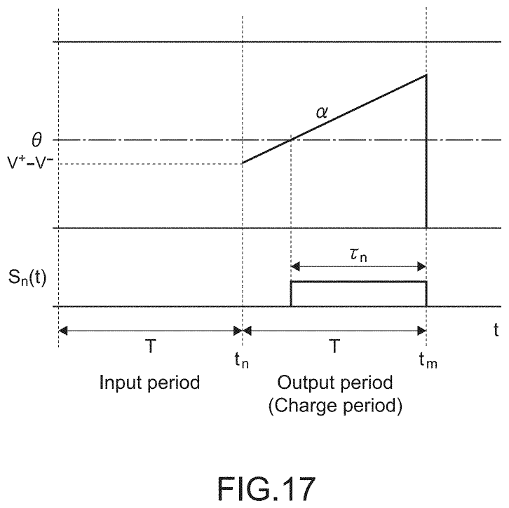

FIG. 16 is a schematic circuit diagram showing another example of the analog circuit 3 according to the PWM method. FIG. 17 is a diagram for describing an example of calculation of the multiply-accumulate signal by the analog circuit 3 shown in FIG. 16.

In the analog circuit 3 illustrated in FIG. 16, a differential amplification circuit 26 outputs a charge (V⁺−V⁻) corresponding to the difference between the total amount of positive weight charge and the total amount of negative weight charge and the charge (V⁺−V⁻) is stored in the capacitor 13 included in the accumulation unit 11. The specific configuration of the differential amplification circuit 26 is not limited, and may be arbitrarily designed.

At the start timing of the input period T, switches 16a, 16b, and 16c are turned on and the switch 16b is turned off. Then, the input signal is input within the input period T. The charge (V⁺−V⁻) output by the differential amplification circuit 26 is accumulated in the capacitor 13. It should be noted that the illustration of the charge accumulation state in the input period T is omitted from FIG. 17.

At the end timing tₙ of the input period T, the switch 16c is turned off and the switch 16d is turned on. Then, as shown in FIG. 17, charging by the charging unit 15 (current source 25) is started at the end timing tₙ of the input period T.

Moreover, the comparator 22 of the signal output unit 12 detects the timing at which the voltage retained by the capacitor 13 exceeds the threshold value θ. Based on the detected timing, the signal generation unit 23 calculates the multiply-accumulate signal (PWM signal) “Sₙ(t)”.

Thus, the multiply-accumulate signal “Sₙ(t)” can be output by performing the threshold determination on the charge corresponding to the difference (V⁺−V⁻) between the total amount of positive weight charge and the total amount of negative weight charge. Also, the charging according to the common charging mode and the threshold determination using the common threshold value can be performed on the one or more analog circuits 3. For example, in a case of arranging the plurality of analog circuits 3 in parallel, the charging according to the common charging mode and the threshold determination using the common threshold value are performed. Accordingly, it is possible to realize efficient and high-speed arithmetic processing.

In the above description, the case where the plurality of analog circuits is arranged in parallel has been mainly described. The present technology is not limited thereto, and can also be applied to a single analog circuit. For example, a positive weight value accumulation unit and a negative weight accumulation unit are charged on the common charging mode. Then, the threshold determination is performed on the positive weight charge and the negative weight charge by using the common threshold value. Accordingly, it is possible to realize efficient and high-speed arithmetic processing.

In the above description, the case of outputting the multiply-accumulate signal on the basis of the timing at which the voltage retained by the accumulation unit increases beyond the threshold value has been exemplified. However, a configuration to output the multiply-accumulate signal on the basis of the timing at which the voltage retained by the accumulation unit decreases beyond the threshold voltage may be employed. For example, charging is performed in advance until the voltage of the capacitor that functions as the accumulation unit reaches a predetermined preset value. After the sum of charges each corresponding to the product value of the signal value and the weight value is accumulated, the capacitor is discharged at a predetermined rate. In such a case, the multiply-accumulate signal can be output on the basis of a timing at which the voltage retained by the capacitor decreases beyond the threshold value. As a matter of course, the present technology is not limited to such a configuration. It should be noted that in the present disclosure, discharging the capacitor is included in charging the capacitor with negative charges.

In the above description, the case where the pair of output lines is used has been described. The present technology is not limited thereto, and three or more output lines may be provided. That is, the present technology described above can be applied also in a case where one or more any number of output lines are used. For example, the multiplication unit includes a resistor that is connected between an associated input line and any one of the one or more output lines and defines a weight value, and outputs a charge corresponding to the product value to the output line to which the resistor is connected. As a matter of course, the present technology is not limited thereto.

The configurations of the arithmetic apparatus, the multiply-accumulate devices, the analog circuits, the synapse circuits, the neuron circuits, and the like, the method of generating the multiply-accumulate signal, and the like described above with reference to the drawings belong to merely an embodiment, and can be arbitrarily modified without departing from the gist of the present technology. That is, any other configurations, methods, and the like for carrying out the present technology may be employed.

In the present disclosure, “the same”, “equal”, “orthogonal”, “parallel”, and the like are concepts including “substantially the same”, “substantially equal”, “substantially orthogonal”, “substantially parallel”, and the like. For example, the states included in a predetermined range (e.g., a range of ±10%) with reference to “completely the same”, “completely equal”, “completely orthogonal”, “completely parallel”, and the like are also included.

At least two of the features of the present technology described above can also be combined. In other words, various features described in the respective embodiments may be combined discretionarily irrespective of the embodiments. Moreover, the various effects described above are not limitative but are merely illustrative, and other effects may be provided.

It should be noted that the present technology can also take the following configurations.
(1) An arithmetic apparatus, including:

a plurality of input lines into each of which an electrical signal corresponding to an input value is input within a predetermined input period; and

one or more multiply-accumulate devices each including
a plurality of multiplication units that generates, on the basis of the electrical signal input into each of the plurality of input lines, a charge corresponding to a product value obtained by multiplying the input value by a weight value,
an accumulation unit that accumulates the charge corresponding to the product value generated by each of the plurality of multiplication units,
a charging unit that charges, after the input period, the accumulation unit in which the charge corresponding to the product value is accumulated, and
an output unit that outputs, after charging by the charging unit starts, a multiply-accumulate signal representing a sum of the product values by performing threshold determination on a voltage retained by the accumulation unit by using a predetermined threshold value, in which

in the one or more multiply-accumulate devices, the charging by the charging unit is performed on a common charging mode and a common threshold value is set as the predetermined threshold value.
(2) The arithmetic apparatus according to (1), in which

the one or more multiply-accumulate devices are a plurality of multiply-accumulate devices connected in parallel to the plurality of input lines.
(3) The arithmetic apparatus according to (1) or (2), in which

the common charging mode includes charging in which a same charge signal is supplied during a common charging period.
(4) The arithmetic apparatus according to any one of (1) to (3), in which

the common charging mode includes charging at a common charging speed.
(5) The arithmetic apparatus according to any one of (1) to (4), in which

the common charging mode includes charging according to a common time constant.
(6) The arithmetic apparatus according to any one of (1) to (5), in which

defining a sum total of absolute values of the weight values set in the plurality of multiplication units as a weight sum total value, the common charging mode includes charging based on a maximum value of the weight sum total value among the one or more multiply-accumulate devices.
(7) The arithmetic apparatus according to (5) or (6), in which

each of the one or more multiply-accumulate devices includes a charge output line,

the plurality of multiplication units outputs the charge corresponding to the product value to the charge output line, and

the common charging mode includes charging in which a time constant associated with the output of the charge corresponding to the product value to the charge output line by the plurality of multiplication units the weight sum total value of which is the maximum value is used as the common time constant.
(8) The arithmetic apparatus according to any one of (1) to (7), in which

the common threshold value is set on the basis of a duration of the input period.
(9) The arithmetic apparatus according to any one of (1) to (8), in which

defining a sum total of absolute values of the weight values set in the plurality of multiplication units as a weight sum total value, the common threshold value is set on the basis of a maximum value of the weight sum total value among the one or more multiply-accumulate devices.
(10) The arithmetic apparatus according to any one of (1) to (9), in which

the common charging mode includes charging in which a same charge signal is supplied during the common charging period, and

the charging unit includes a charging line that is connected to the accumulation unit and supplies the same charge signal to the accumulation unit during the common charging period.
(11) The arithmetic apparatus according to any one of (1) to (9), in which

the common charging mode includes charging in which a same charge signal is supplied during the common charging period, and

the charging unit supplies the same charge signal to the accumulation unit via the plurality of input lines during the common charging period.
(12) The arithmetic apparatus according to any one of (1) to (11), in which

the plurality of multiplication units includes at least one of a positive weight multiplication unit that generates a positive weight charge corresponding to a product value obtained by multiplying the input value by a positive weight value or a negative weight multiplication unit that generates a negative weight charge corresponding to a product value obtained by multiplying the input value by a negative weight value,

the accumulation unit includes a positive charge accumulation unit capable of accumulating the positive weight charge generated by the positive weight multiplication unit and a negative charge accumulation unit capable of accumulating the negative weight charge generated by the negative weight multiplication unit,

the charging unit charges the positive charge accumulation unit and the negative charge accumulation unit on the common charging mode, and

the output unit outputs the multiply-accumulate signal by performing threshold determination on each of the positive charge accumulation unit and the negative charge accumulation unit by using the common threshold value.
(13) The arithmetic apparatus according to (12), in which

defining a sum total of the positive weight values set in the plurality of multiplication units as a positive sum total value and a sum total of the absolute values of the negative weight values as a negative sum total value, the common charging mode includes charging based on a maximum value among the positive sum total values and the negative sum total values in the one or more multiply-accumulate devices.
(14) The arithmetic apparatus according to (13), in which

each of the one or more multiply-accumulate devices includes a positive charge output line and a negative charge output line,

the positive charge multiplication unit outputs the positive weight charge to the positive charge output line,

the negative charge multiplication unit outputs the negative weight charge to the negative charge output line, and

assuming that the maximum value among the positive sum total values and the negative sum total values in the one or more multiply-accumulate devices is a maximum sum total value,
that the positive weight charge or the negative weight charge related to the maximum sum total value is a maximum weight charge, and
that the positive charge output line or the negative charge output line from which the maximum weight charge is output is a maximum charge output line,

defining a time constant associated with the output of the maximum weight charge to the maximum charge output line as a common time constant, the common charging mode includes charging according to the common time constant.
(15) The arithmetic apparatus according to any one of (12) to (14), in which

defining a sum total of the positive weight values set in the plurality of multiplication units as a positive sum total value and a sum total of the absolute values of the negative weight values as a negative sum total value, the common threshold value is set on the basis of a maximum value among the positive sum total values and the negative sum total values in the one or more multiply-accumulate devices.
(16) The arithmetic apparatus according to any one of (12) to (15), in which

the positive weight value and the absolute value of the negative weight value are fixed to a same value, set to any one of the plurality of values different from each other, or randomly set, and

in the one or more multiply-accumulate devices, a value obtained by adding the positive sum total value and the negative sum total value is a common value.
(17) The arithmetic apparatus according to any one of (12) to (15), in which

the positive weight value and the absolute value of the negative weight value are fixed to a same value, set to any one of the plurality of values different from each other, or randomly set, and

in the one or more multiply-accumulate devices, a value obtained by adding the positive sum total value and the negative sum total value is a random value.
(18) The arithmetic apparatus according to any one of (12) to (17), in which

the common charging mode includes charging in which a same charge signal is supplied during the common charging period, and

the charging unit includes a charging line that is connected to the positive charge accumulation unit and the negative charge accumulation unit and supplies the same charge signal to the positive charge accumulation unit and the negative charge accumulation unit during the common charging period.
(19) The arithmetic apparatus according to any one of (12) to (18), in which

the common charging mode includes charging in which a same charge signal is supplied during the common charging period, and

the charging unit supplies the same charge signal to the positive charge accumulation unit and the negative charge accumulation unit via the plurality of input lines during the common charging period.
(20) A multiply-accumulate system, including:

a plurality of input lines into each of which an electrical signal corresponding to an input value is input within a predetermined input period;

one or more multiply-accumulate devices each including
a plurality of multiplication units that generates, on the basis of the electrical signal input into each of the plurality of input lines, a charge corresponding to a product value obtained by multiplying the input value by a weight value,
an accumulation unit that accumulates the charge corresponding to the product value generated by each of the plurality of multiplication units,
a charging unit that charges, after the input period, the accumulation unit in which the charge corresponding to the product value is accumulated, and
an output unit that outputs, after charging by the charging unit starts, a multiply-accumulate signal representing a sum of the product values by performing threshold determination on a voltage retained by the accumulation unit by using a predetermined threshold value; and

a network circuit configured by connecting the plurality of analog circuits, in which

in the one or more analog circuits, the charging by the charging unit is performed on a common charging mode and a common threshold value is set as the predetermined threshold value.
(21) The arithmetic apparatus according to any one of (1) to (19), in which

the electrical signal corresponding to the input value is a pulse signal whose ON time duration with respect to the input period corresponds to the input value.
(22) The arithmetic apparatus according to any one of (1) to (19) and (21), in which

the common charging period has a duration equal to the input period.

### REFERENCE SIGNS LIST

T input period
θ threshold value
1 signal line
3 analog circuit
6 input signal line
7 pair of output lines
7a positive charge output line
7b negative charge output line
8 synapse circuit (multiplication unit)
8a synapse circuit (positive weight multiplication unit)
8b synapse circuit (negative weight multiplication unit)
9 neuron circuit
10 output signal line
11 accumulation unit
12 signal output unit
13 capacitor
15 charging unit
17 resistor
17a positive resistor
17b negative resistor
19 charging line
20, 20a, 20b resistor in charging unit
22, 22a, 22b comparator
23 signal generation unit
25, 25a, 25b current source
26 differential amplification circuit
100 arithmetic apparatus

1. An arithmetic apparatus, comprising:
a plurality of input lines into each of which an electrical signal corresponding to an input value is input within a predetermined input period; and
one or more multiply-accumulate devices each including
a plurality of multiplication units that generates, on a basis of the electrical signal input into each of the plurality of input lines, a charge corresponding to a product value obtained by multiplying the input value by a weight value,
an accumulation unit that accumulates the charge corresponding to the product value generated by each of the plurality of multiplication units,
a charging unit that charges, after the input period, the accumulation unit in which the charge corresponding to the product value is accumulated, and
an output unit that outputs, after charging by the charging unit starts, a multiply-accumulate signal representing a sum of the product values by performing threshold determination on a voltage retained by the accumulation unit by using a predetermined threshold value, wherein
in the one or more multiply-accumulate devices, the charging by the charging unit is performed on a common charging mode and a common threshold value is set as the predetermined threshold value.

2. The arithmetic apparatus according to claim 1, wherein
the one or more multiply-accumulate devices are a plurality of multiply-accumulate devices connected in parallel to the plurality of input lines.

3. The arithmetic apparatus according to claim 1, wherein
the common charging mode includes charging in which a same charge signal is supplied during a common charging period.

4. The arithmetic apparatus according to claim 1, wherein
the common charging mode includes charging at a common charging speed.

5. The arithmetic apparatus according to claim 1, wherein
the common charging mode includes charging according to a common time constant.

6. The arithmetic apparatus according to claim 1, wherein
defining a sum total of absolute values of the weight values set in the plurality of multiplication units as a weight sum total value, the common charging mode includes charging based on a maximum value of the weight sum total value among the one or more multiply-accumulate devices.

7. The arithmetic apparatus according to claim 5, wherein
each of the one or more multiply-accumulate devices includes a charge output line,
the plurality of multiplication units outputs the charge corresponding to the product value to the charge output line, and
the common charging mode includes charging in which a time constant associated with the output of the charge corresponding to the product value to the charge output line by the plurality of multiplication units the weight sum total value of which is the maximum value is used as the common time constant.

8. The arithmetic apparatus according to claim 1, wherein
the common threshold value is set on a basis of a duration of the input period.

9. The arithmetic apparatus according to claim 1, wherein
defining a sum total of absolute values of the weight values set in the plurality of multiplication units as a weight sum total value, the common threshold value is set on a basis of a maximum value of the weight sum total value among the one or more multiply-accumulate devices.

10. The arithmetic apparatus according to claim 1, wherein
the common charging mode includes charging in which a same charge signal is supplied during the common charging period, and
the charging unit includes a charging line that is connected to the accumulation unit and supplies the same charge signal to the accumulation unit during the common charging period.

11. The arithmetic apparatus according to claim 1, wherein
the common charging mode includes charging in which a same charge signal is supplied during the common charging period, and
the charging unit supplies the same charge signal to the accumulation unit via the plurality of input lines during the common charging period.

12. The arithmetic apparatus according to claim 1, wherein
the plurality of multiplication units includes at least one of a positive weight multiplication unit that generates a positive weight charge corresponding to a product value obtained by multiplying the input value by a positive weight value or a negative weight multiplication unit that generates a negative weight charge corresponding to a product value obtained by multiplying the input value by a negative weight value,
the accumulation unit includes a positive charge accumulation unit capable of accumulating the positive weight charge generated by the positive weight multiplication unit and a negative charge accumulation unit capable of accumulating the negative weight charge generated by the negative weight multiplication unit,
the charging unit charges the positive charge accumulation unit and the negative charge accumulation unit on the common charging mode, and
the output unit outputs the multiply-accumulate signal by performing threshold determination on each of the positive charge accumulation unit and the negative charge accumulation unit by using the common threshold value.

13. The arithmetic apparatus according to claim 12, wherein
defining a sum total of the positive weight values set in the plurality of multiplication units as a positive sum total value and a sum total of the absolute values of the negative weight values as a negative sum total value, the common charging mode includes charging based on a maximum value among the positive sum total values and the negative sum total values in the one or more multiply-accumulate devices.

14. The arithmetic apparatus according to claim 13, wherein
each of the one or more multiply-accumulate devices includes a positive charge output line and a negative charge output line,
the positive charge multiplication unit outputs the positive weight charge to the positive charge output line,
the negative charge multiplication unit outputs the negative weight charge to the negative charge output line, and
assuming that the maximum value among the positive sum total values and the negative sum total values in the one or more multiply-accumulate devices is a maximum sum total value,
that the positive weight charge or the negative weight charge related to the maximum sum total value is a maximum weight charge, and
that the positive charge output line or the negative charge output line from which the maximum weight charge is output is a maximum charge output line,
defining a time constant associated with the output of the maximum weight charge to the maximum charge output line as a common time constant, the common charging mode includes charging according to the common time constant.

15. The arithmetic apparatus according to claim 12, wherein
defining a sum total of the positive weight values set in the plurality of multiplication units as a positive sum total value and a sum total of the absolute values of the negative weight values as a negative sum total value, the common threshold value is set on a basis of a maximum value among the positive sum total values and the negative sum total values in the one or more multiply-accumulate devices.

16. The arithmetic apparatus according to claim 12, wherein
the positive weight value and the absolute value of the negative weight value are fixed to a same value, set to any one of the plurality of values different from each other, or randomly set, and
in the one or more multiply-accumulate devices, a value obtained by adding the positive sum total value and the negative sum total value is a common value.

17. The arithmetic apparatus according to claim 12, wherein
the positive weight value and the absolute value of the negative weight value are fixed to a same value, set to any one of the plurality of values different from each other, or randomly set, and
in the one or more multiply-accumulate devices, a value obtained by adding the positive sum total value and the negative sum total value is a random value.

18. The arithmetic apparatus according to claim 12, wherein
the common charging mode includes charging in which a same charge signal is supplied during the common charging period, and
the charging unit includes a charging line that is connected to the positive charge accumulation unit and the negative charge accumulation unit and supplies the same charge signal to the positive charge accumulation unit and the negative charge accumulation unit during the common charging period.

19. The arithmetic apparatus according to claim 12, wherein
the common charging mode includes charging in which a same charge signal is supplied during the common charging period, and
the charging unit supplies the same charge signal to the positive charge accumulation unit and the negative charge accumulation unit via the plurality of input lines during the common charging period.

20. A multiply-accumulate system, comprising:
a plurality of input lines into each of which an electrical signal corresponding to an input value is input within a predetermined input period;
one or more multiply-accumulate devices each including
a plurality of multiplication units that generates, on a basis of the electrical signal input into each of the plurality of input lines, a charge corresponding to a product value obtained by multiplying the input value by a weight value,
an accumulation unit that accumulates the charge corresponding to the product value generated by each of the plurality of multiplication units,
a charging unit that charges, after the input period, the accumulation unit in which the charge corresponding to the product value is accumulated, and
an output unit that outputs, after charging by the charging unit starts, a multiply-accumulate signal representing a sum of the product values by performing threshold determination on a voltage retained by the accumulation unit by using a predetermined threshold value; and
a network circuit configured by connecting the plurality of analog circuits, wherein
in the one or more analog circuits, the charging by the charging unit is performed on a common charging mode and a common threshold value is set as the predetermined threshold value.
